(19) United States
(12) Patent Application Publication
(10) Pub. No.: US 2011/0108812 A1
(43) Pub. Date: May 12, 2011

(54) ORGANIC EL DEVICE

(76) Inventors: Shiro Sumita, Kanazawa-shi (JP); Shuhei Yokoyama, Ishikawa-gun (JP); Masuyuki Oota, Hakusan-shi (JP); Satoshi Okutani, Ishikawa-gun (JP)

(21) Appl. No.: 12/914,221

(22) Filed: Oct. 28, 2010

(30) Foreign Application Priority Data
Nov. 6, 2009 (JP) 2009-255269
Nov. 6, 2009 (JP) 2009-255270
Nov. 25, 2009 (JP) 2009-267760

(51) Int. Cl. H01L 51/52

(52) U.S. Cl. 257/40; 257/E51.018

(57) ABSTRACT

According to one embodiment, an organic EL device includes an insulating substrate, switching elements arranged two-dimensionally above the insulating substrate, an insulating layer positioned above the switching elements and provided with contact holes communicating with the switching elements, respectively, pixel electrodes arranged correspondingly with the switching elements, cover members arranged correspondingly with the contact holes, an organic layer extending over the pixel electrodes, the cover members and a portion of the insulating layer positioned below a region between the pixel electrodes, and a counter electrode positioned above the organic layer. Each pixel electrode includes an electrode body positioned above the insulating layer and a contact section extending in the contact hole and electrically connects the electrode body to the switching element. Each cover member covers the contact section and is made of an insulating material.

### CROSS-REFERENCE TO RELATED APPLICATIONS

This application is based upon and claims the benefit of priority from Japanese Patent Applications No. 2009-255269, filed Nov. 6, 2009; No. 2009-255270, filed Nov. 6, 2009; and No. 2009-267760, filed Nov. 25, 2009; the entire contents of all of which are incorporated herein by reference.

### FIELD

Embodiments described herein relate generally to an organic electroluminescence (hereinafter, referred to as EL) device.

### BACKGROUND

In recent years, a display including organic EL elements as display elements has been actively studied. An organic EL element is a light-emitting element, and thus such a display does not require a backlight. Therefore, organic EL displays can be thinner and lighter as compared with liquid crystal displays. Organic EL displays are also more advantageous in achieving a higher response speed, wider viewing angle, and higher contrast as compared with liquid crystal displays.

An organic EL element includes a hole injection electrode (anode), an electron injection electrode (cathode), and an emitting layer interposed therebetween. Emission of an organic EL element is caused by recombination of a hole and an electron injected from the anode and cathode, respectively.

An organic EL display enabling full-color display includes, for example, pixels emitting red, green and blue light. In production of such a display, emitting layers having different emission spectra are formed in patterns which correspond to arrangements of pixels emitting red, green, and blue light. For example, an emitting layer which emits red light is formed by vacuum evaporation using a fine mask which is provided with through-holes correspondingly with the pixels emitting red light. Then, emitting layers emitting green and blue light are formed in this order by repetition of the same processes.

### BRIEF DESCRIPTION OF THE DRAWINGS

FIG. 1 is a sectional view schematically showing an organic EL display according to the first embodiment;

FIG. 2 is a sectional view schematically showing an example of a structure that can be employed in the organic EL elements included in the organic EL display of FIG. 1;

FIG. 3 is a plan view schematically showing an example of a structure that can be employed in the organic EL elements included in the organic EL display of FIG. 1;

FIG. 4 is a sectional view taken along a line IV-IV of the structure shown in FIG. 3;

FIG. 5 is a sectional view schematically showing an organic display according to the second embodiment;

FIG. 6 is a plan view schematically showing an example of a structure that can be employed in the organic EL elements included in the organic EL display of FIG. 5;

FIG. 7 is a sectional view taken along a line VII-VII of the structure shown in FIG. 6;

FIG. 8 is a sectional view schematically showing a modified example of the structure shown in FIG. 7;

FIG. 9 is a sectional view schematically showing an organic EL display according to the third embodiment;

FIG. 10 is a plan view schematically showing an example of a structure that can be employed in the organic EL elements included in the organic EL display of FIG. 9;

FIG. 11 is a sectional view schematically showing a modified example of the organic EL display shown in FIG. 9;

FIG. 12 is a sectional view schematically showing another modified example of the organic EL display shown in FIG. 9;

FIG. 13 is a sectional view schematically showing still another modified example of the organic EL display shown in FIG. 9;

FIG. 14 is a sectional view schematically showing an organic EL display according to the fourth embodiment;

FIG. 15 is a plan view schematically showing an example of a structure that can be employed in the organic EL elements included in the organic EL display of FIG. 14;

FIG. 16 is a sectional view taken along a line XVI-XVI of the structure shown in FIG. 15;

FIG. 17 is a sectional view schematically showing an organic EL display according to the fifth embodiment;

FIG. 18 is a plan view schematically showing an example of the structure that can be employed in the organic EL elements included in the organic EL display of FIG. 17;

FIG. 19 is a sectional view taken along a line XIX-XIX of the structure shown in FIG. 18;

FIG. 20 is a sectional view schematically showing an organic EL display according to the sixth embodiment;

FIG. 21 is a graph showing an example of relation between film thickness of a protective layer 150 and ultraviolet transmittance;

FIG. 22 is a sectional view schematically showing an organic EL display according to the seventh embodiment;

FIG. 23 is a sectional view schematically showing an example of an organic EL display; and

FIG. 24 is a sectional view schematically showing another example of an organic EL display.

### DETAILED DESCRIPTION

In general, according to one embodiment, there is provided an organic EL device comprising an insulating substrate, switching elements, an insulating layer, pixel electrodes, cover members, an organic layer, and a counter electrode. In this organic EL device, the switching elements are two-dimensionally arranged above the insulating substrate. The insulating layer is positioned above the switching elements and is provided with contact holes communicating with the switching elements, respectively. The pixel electrodes are arranged correspondingly with the switching elements, and each of them includes an electrode body positioned above the insulating layer and a contact section extending in the contact hole and electrically connecting the electrode body to the switching element. The cover members are arranged correspondingly with the contact holes, and each of them covers the contact section and is made of an insulating material. The organic layer extends over the pixel electrodes, the cover members and a portion of the insulating layer positioned below a region between the pixel electrodes. The counter electrode is positioned above the organic layer.

According to another embodiment, there is provided an organic EL device comprising an insulating substrate, first to third switching elements, an insulating layer, first to third pixel electrodes, first to third cover members, first to third organic layers, and a counter electrode. In this organic EL device, the first to third switching elements are arranged above the insulating substrate. The insulating layer is positioned above the first to third switching elements, and is provided with the first to third contact holes communicating with the first to third switching elements, respectively. The first pixel electrode includes the first electrode body positioned above the insulating layer and the first contact section extending in the first contact hole and electrically connecting the first electrode body to the first switching element. The second pixel electrode includes the second electrode body positioned above the insulating layer and the second contact section extending in the second contact hole and electrically connecting the second electrode body to the second switching element. The third pixel electrode includes the third electrode body positioned above the insulating layer and the third contact section extending in the third contact hole and electrically connecting the third electrode body to the third switching element. The first to third cover members each are made of an insulating material and cover the first to third contact sections, respectively. The first organic layer extends over the first to third pixel electrodes, the first to third cover members, and a portion of the insulating layer below a region between any two of the first to third pixel electrodes, and it emits light at a portion corresponding to the first pixel electrode and causes quenching at portions corresponding to the second and third pixel electrodes. The second organic layer extends above the first organic layer, and it emits light at portions corresponding to the first and second pixel electrodes and causes quenching at a portion corresponding to the third pixel electrode. The third organic layer extends above the second organic layer, and it emits light at portions corresponding to the first and second pixel electrodes and causes quenching at a portion corresponding to the third pixel electrode. The counter electrode is positioned above the first organic layer.

According to still another embodiment, there is provided an organic EL device comprising an insulating substrate, switching elements, an insulating layer, pixel electrodes, a cover member, an organic layer, and a counter electrode. In this organic EL device, the switching elements are two-dimensionally arranged above the insulating substrate. The insulating layer is positioned above the switching elements and is provided with contact holes communicating with the switching elements, respectively. The pixel electrodes are arranged correspondingly with the switching elements, and each includes an electrode body positioned above the insulating layer and a contact section extending in the contact hole and electrically connecting the electrode body to the switching element. The cover member is made of an insulating material and covers the contact section and a portion of the insulating layer positioned below a region between the pixel electrodes. The organic layer extends above the pixel electrodes and the cover member. The counter electrode is positioned above the organic layer.

Examples of organic EL devices which are applied to organic EL displays will be described below with reference to the drawings. In the drawings, the same reference characters denote components having the same or similar functions and duplicates descriptions will be omitted. In the drawings, a X direction and Y direction are parallel to the display surface and intersect with each other. For example, the X and Y directions are orthogonal to each other. A Z direction is a direction which is perpendicular to the display surface.

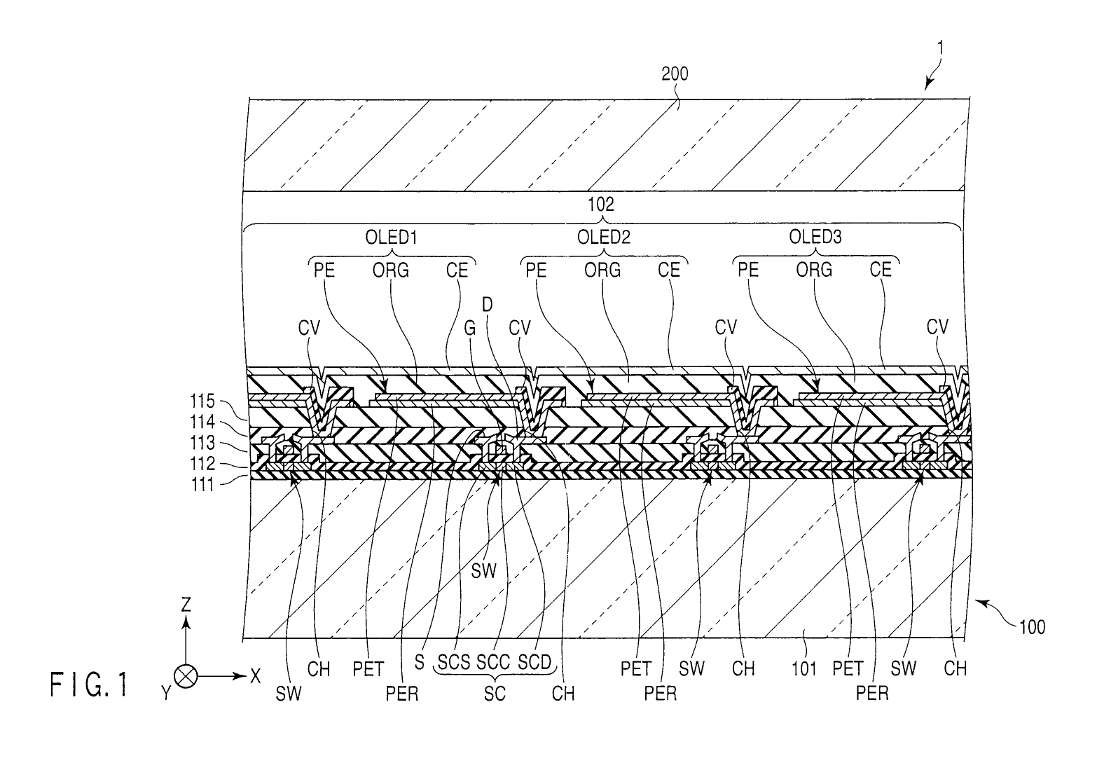

The first embodiment relates to an organic EL display that employs an active matrix driving method. The organic EL display according to the first embodiment is explained below with reference to FIGS. 1 to 4.

The organic EL display according to the first embodiment includes the display panel shown in FIG. 1. The display panel 1 includes switching elements SW, the first organic EL elements OLED1, the second organic EL elements OLED2, and the third organic EL elements OLED3. This display panel 1 is a top emission type which emits light from a side of a sealing substrate 200. The display panel 1 may be a bottom emission type which emits light from a side of an array substrate 100.

The array substrate 100 is provided with an insulating substrate 101 having a light-transmitting property such as a glass substrate and plastic substrate. Above the insulating substrate 101, the switching elements SW and organic EL elements OLED1 to OLED3 are arranged in an active area 102 for displaying images.

The first insulating layer 111 is provided over the insulating substrate. The first insulating layer 111 extends over almost the entire active area 102. The insulating layer 111 is made of, for example, an inorganic compound such as silicon dioxide and silicon nitride.

On the insulating layer 111, semiconductor layers SC of the switching elements SW are arranged. These semiconductor layers SC are made of, for example, polysilicon. In each of the semiconductor layers, a source region SCS and drain region SCD between which a channel region SCC is sandwiched are formed.

The semiconductor layers SC are covered by the second insulating layer 112. The insulating layer 112 also covers the first insulating layer 111. The insulating layer 112 extends over almost the entire active area 102. The insulating layer 112 is made of, for example, an inorganic compound such as silicon oxide and silicon nitride.

At positions of the channel regions SCC on the insulating layer 112, gate electrodes G of the switching elements are arranged. In this example, the switching elements SW are top-gate type p-channel thin-film transistors (TFTs). The gate electrodes G are covered by the third insulating layer 113. The insulating layer 113 also covers the second insulating layer 112. The insulating layer 113 extends over almost the entire active area 102. The insulating layer 113 is made of, for example, an inorganic compound such as silicon dioxide and silicone nitride.

On the insulating layer 113, source electrodes S and drain electrodes D of the switching elements are arranged. The source electrodes S are in contact with the source regions SCS of the semiconductor layers SC. The drain electrodes D are in contact with the drain regions SCD of the semiconductor layers SC. The gate electrodes G, source electrodes S, and drain electrodes D of the switching elements SW are made of, for example, conductive materials such as molybdenum (Mo), tungsten (W), aluminum (Al), titanium (Ti), and the combination thereof.

The source electrodes S and drain electrodes D are covered by the first interlayer insulator 114. The interlayer insulator 114 also covers the third insulating layer 113. The interlayer insulator 114 extends over almost the entire active area 102. The interlayer insulator 114 is, for example, an inorganic insulating layer. The interlayer insulator 114 is made of, for example, an inorganic compound such as silicon dioxide and silicon nitride. The interlayer insulator 114 serves as a passivation layer above the switching elements SW.

On the interlayer insulator 114, the second interlayer film 115 is provided. The interlayer insulator 115 extends over almost the entire active area 102. The interlayer film 115 is, for example, an organic insulating layer. The interlayer insulator 115 is formed from, for example, an organic compound such as ultraviolet curing resin and thermosetting resin.

The combination of the interlayer insulators 114 and 115 corresponds to the insulating layer provided above the switching elements SW. Namely, the interlayer insulators 114 and 115 are arranged between the switching elements SW and the organic EL elements OLED1 to OLED3. In the insulating layer including the interlayer insulators 114 and 115, contact holes CH communicating with switching elements SW are provided. Specifically, contact holes CH are provided at positions of the drain electrodes D of the switching elements SW.

Each of the organic EL elements OLED1 to OLED3 includes a pixel electrode PE, an organic layer ORG and a counter electrode CE.

The pixel electrodes PE are arranged on the interlayer insulator 115. Each of the pixel electrodes extends in the contact hole CH, and is electrically connected with the drain electrode D of the switching element SW which is exposed at the contact hole CH. The pixel electrode PE corresponds, for example, to an anode. The pixel electrodes PE are spaced apart from one another.

The portion of each pixel electrode PE connected to the switching element SW is covered by a cover member CV. That is, the cover members CV are arranged correspondingly with the pixel electrodes PE to form an islands structure. Specifically, the cover member CV partially covering the pixel electrode of the organic EL element OLED1, the cover member CV partially covering the pixel electrode of the organic EL element OLED2, and the cover member CV partially covering the pixel electrode OLED3 are spaced apart from one another.

The structure of connection between the pixel electrode PE and the switching element SW and the peripheral structure thereof will be described later in detail.

To the pixel electrode, various structures can be employed. In the examples shown herein, the pixel electrode PE has a two-layer structure of a reflecting layer PER and transmitting layer PET. Reflecting layers PER are arranged on the interlayer insulator 115. Transmitting layers PET are arranged on the reflecting layers PER. The reflecting layers PER are made of, for example, conductive materials having a light-reflecting property such as silver (Ag) and aluminum (Al). The transmitting layers PET are made of, for example, conductive materials having a light-transmitting property such as indium tin oxide (ITO) and indium zinc oxide (IZO).

The pixel electrodes PE may be reflecting layers or transmitting layers having a single layer structure. Alternatively, the pixel electrodes PE may have a multilayered structure including three or more layers. When a display panel 1 is a top emission type, the pixel electrode includes at least the reflecting layer PER. When the display panel 1 is a bottom emission type, the pixel electrode does not include the reflecting layer PER.

The organic layer ORG is provided on the pixel electrodes PE. The organic layer ORG is a continuous film which extends over almost the entire active area 102. That is, the organic layer ORG extends over the pixel electrodes, cover members CV, and a portion of the interlayer insulation film 115 below a region between any two of the pixel electrodes PE.

The organic layer ORG includes an emitting layer. The organic layer ORG may further include one or more layers such as a hole injection layer, hole-transporting layer, electron injection layer, and electron-transporting layer. The material of the emitting layer may be a fluorescent material or phosphorescent material. In the organic layer ORG, when one or more layers include an organic compound or organometallic compound, the other layers may or may not include an organic compound or organometallic compound.

The counter electrode is provided on the organic layer ORG. In this example, the counter electrode CE corresponds to a cathode. The counter electrode CE is a continuous film which extends over almost the entire active area 102.

The counter electrode is, for example, a semitransparent layer. The semitransparent layer is made of, for example, conductive materials such as magnesium (Mg) and silver (Ag). The counter electrode CE may have a two-layer structure of a semitransparent layer and transmitting layer or a single layer structure of a transmitting layer or semitransparent layer. The transmitting layer is made of, for example, conductive materials having a light-transmitting property such as ITO and IZO. When the display panel 1 is bottom emission type, the counter electrode CE includes a reflecting layer or semitransparent layer.

A sealing substrate 200 is positioned above the organic EL elements OLED1 to OLED3. The sealing substrate 200 is an insulating substrate having a light-transmitting property such as a glass substrate and plastic substrate.

In this example, the array substrate 100 and sealing substrate 200 are separated from each other, and a space is formed between them. Between the array substrate 100 and the sealing substrate 200, a resin layer and a protective layer covering the organic EL elements OLED1 to OLED3 may be arranged. The protective layer is made of an insulating material which has a light-transmitting property and is difficult for moisture to permeate, for example, an inorganic compound such as silicon nitride and silicon oxynitride. The protective layer covers organic EL elements OLED1 to OLED3 and serves as a moisture barrier layer which prevents moisture from permeating the organic EL elements OLED1 to OLED3. The resin layer is formed from an organic compound having a light-transmitting property such as thermosetting resin and ultraviolet curing resin. The resin layer serves as a filler layer which fills the space between the array substrate 100 and sealing substrate 200 or as an adhesion layer which bonds the array substrate 100 and sealing substrate 200 together.

In this display panel 1, the organic layer ORG includes one or more emitting layers. Each emitting layer is a continuous layer which extends over the organic EL elements OLED1 to OLED3. However, luminous colors of the organic EL elements OLED1 to OLED3 differ from one another. In this example, the luminous color of the organic EL element OLED1, that of the organic EL element OLED2, and that of the organic EL element OLED3 are red, green, and blue, respectively.

Here, the range of 595 nm to 800 nm is defined as the first wavelength range, and a color of light having a main wavelength within the first wavelength range is referred to as red. The wavelength range which is longer than 490 nm and shorter than 595 nm is defined as the second wavelength range, and a color of light having a main wavelength within the second wavelength range is referred to as green. The range of 400 nm to 490 nm is defined as the third wavelength range, and a color of light having a main wavelength within the third wavelength range is referred to as blue.

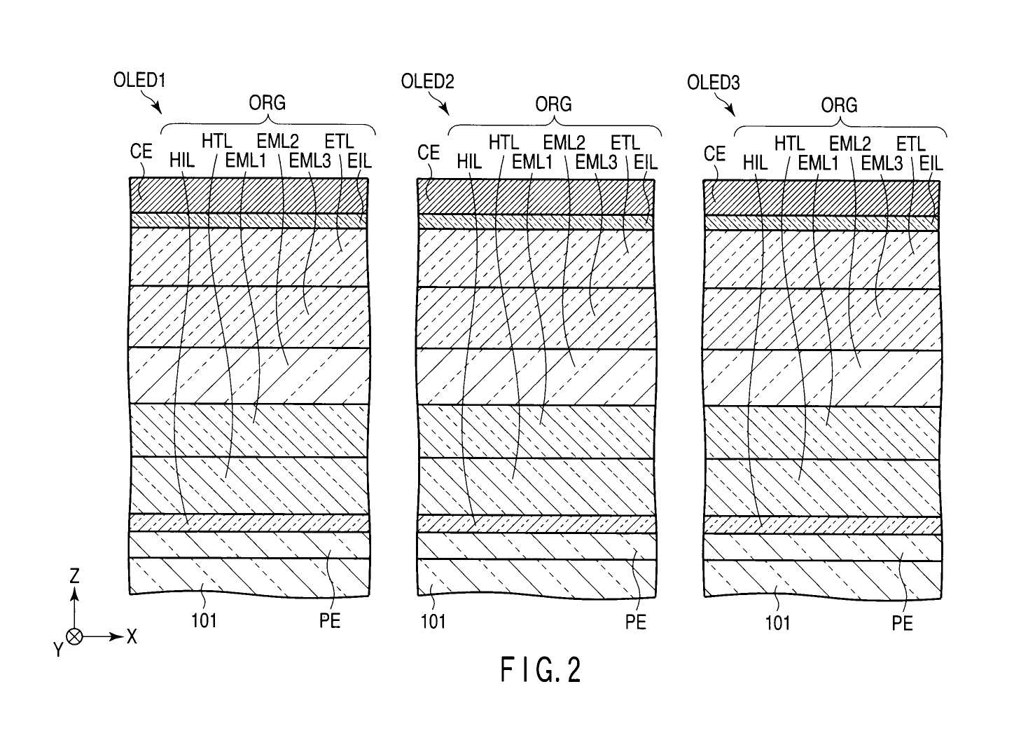

An example of a structure that can be employed in the organic layer ORG will be described below with reference to FIG. 2.

The organic layer ORG shown in FIG. 2 includes a hole injection layer HIL, a hole-transporting layer HTL, the first emitting layer EML1, the second emitting layer EML2, the third emitting layer EML3, an electron-transporting layer ETL, and an electron injection layer EIL. One or more of the hole injection layer HIL, hole-transporting layer HTL, electron-transporting ETL, and electron injection layer EIL can be omitted. Each of the layers included in the organic layer ORG is a continuous film which extends over the organic EL elements OLED1 to OLED3.

The emitting layer EML1 includes the first dopant having a red luminous color. The emitting layer EML2 includes the second dopant having a green luminous color. The emitting layer EML3 includes the third dopant having a blue luminous color. Each of the emitting layers EML1 to EML3 further includes a host material typically. Host materials of the emitting layers EML1 to EML3 may or may not be the same.

A portion of the emitting layer EML1 which is used for the organic EL elements OLED2 and OLED3 has been subjected to a quenching treatment. Further, a portion of the emitting layer EML2 which is used for the organic EL element OLED3 has been subjected to a quenching treatment. The “quenching treatment” means a treatment which reduces emission efficiency or a treatment which shifts a main wavelength of a luminous color to a longer wavelength. The quenching treatment includes, for example, irradiation with light such as ultraviolet ray.

In the first organic EL element OLED1, a red color is displayed by emission of the first dopant. In the second organic EL element OLED2, the first dopant is quenched and a green color is displayed by emission of the second dopant. In the third organic EL element OLED3, the first and second dopants are quenched and a blue color is displayed by emission of the third dopant.

The emitting layer may not have a three-layer structure. For example, the emitting layer may have a two-layer structure including the first and second emitting layers or a single layer structure having only the first emitting layer. In the case of the two-layer structure, the first emitting layer may includes at least one of the second and third dopants in addition to the first dopant, and the second emitting layer may include at least one of the first and third dopants in addition to the second dopant. In the case of the single layer structure, the first emitting layer may include the first to third dopants.

As the first to third dopants, those which change light-emitting performance by light irradiation are used. For example, as the first to third dopants, those which reduce the light-emitting performance by light irradiation are used. Alternatively, as the first to third dopants, those which change luminous colors by light irradiation are used.

As such dopants, for example, those which change conformation by light irradiation can be used. For example, a dopant which isomerizes by light irradiation can be used. As an example of isomerization, isomerization between cis-isomer and trans-isomer will be briefly described below. A cis form is a conformation of a molecule which has two side residues or atomic groups being on the same side with respect to the main structure such as double bond and planar ring(s). A trans form is a conformation of a molecule which has two side residues or atomic groups being on opposite sides with respect to the main structure. For example, a dopant which isomerizes from a cis form to a trans form by irradiation with light such as ultraviolet light changes the light-emitting performance when irradiated with light. Similarly, a dopant which isomerizes from a trans form to a cis form changes its light-emitting performance when irradiated with light. Such materials are, for example, photochromic materials.

A dopant causing photoisomerization is, for example, those referred to as a photoconvertible protein or fluorescent protein. For example, the fluorescent protein includes those which are activated by ultraviolet irradiation and then changes from a quenching state to a state which can emit light, and those which vary an emission wavelength by ultraviolet irradiation. Such materials can be used as the above-mentioned dopant.

Alternatively, a material which forms a chemical bond with an additive or host material included in the emitting layer to change the light-emission performance can be used as the dopant.

The display panel 1 shown in FIG. 1 employs a structure in which a partition for separating the organic EL elements OLED1 to OLED3 from one another is omitted.

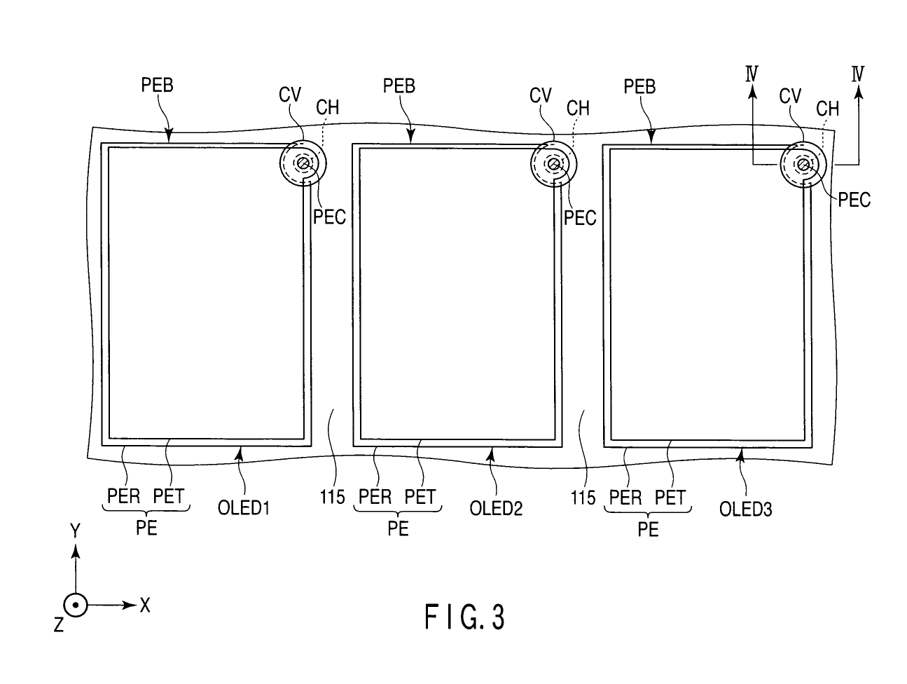

FIG. 3 is a plan view of the organic EL elements OLED1 to OLED3 shown in FIG. 1. In FIG. 3, the organic layer ORG and counter electrode CE are omitted, and the pixel electrodes PE, contact holes CH and the structure nearby are shown.

The organic EL elements OLED1 to OLED3 have almost the same structures. The organic EL elements OLED1 to OLED3 are arranged in the X direction. The pixel electrodes PE of the organic EL elements OLED1 to OLED3 are spaced apart from one another. The second interlayer insulator 115 is exposed between the adjacent pixel electrodes PE. Each of the pixel electrodes PE includes a reflecting layer PER and transmitting layer PET each having an approximate rectangular shape.

The contact holes CH communicate with the switching elements SW as shown in FIG. 1. Each of the contact holes CH is provided in the proximity of one corner of the pixel electrode PE as shown in FIG. 3. In the contact holes CH and in the proximity thereof, the reflecting layers PER do not exist. The transmitting layers PET are placed on the top surfaces of the refection layers PER and extend in the contact holes and in the proximity thereof. The sidewalls of the contact holes CH are covered almost entirely by the transmitting layers PET. These transmitting layers PET are connected to the switching elements SW as shown in FIG. 1. Portions of the transmitting layers PET which are positioned in the contact holes CH are contact portions PEC shown in FIG. 3. Portions of the pixel electrodes PE except the contact portions PE are electrode main bodies PEB. The contact portions PEC form recessed portions in the contact holes CH, each of which extends along the length direction of the contact hole CH.

The cover members CV cover the contact portions PEC. In the example shown, the cover members CV further cover the transmitting layers PET and the portions of the second interlayer insulator 115 which are positioned in the proximity of the contact holes CH. The cover members CV are made of an insulating material. The insulating material is an inorganic compound such as silicon nitride.

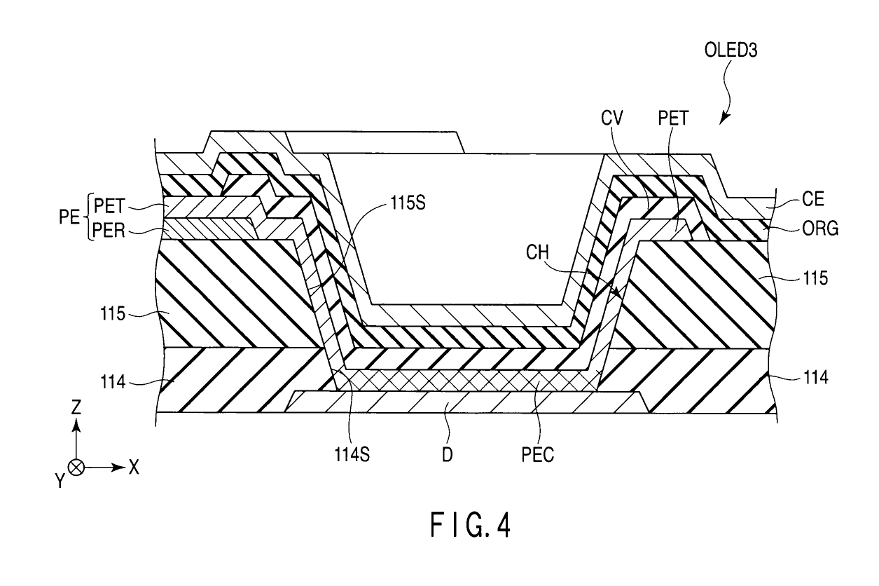

FIG. 4 is a sectional view taken along line IV-IV of the third organic EL element OLED3 shown in FIG. 3. In FIG. 4, a part of the structural elements are omitted.

Between the drain electrodes D of the switching elements and the pixel electrodes PE, the first interlayer insulator 114 and the second interlayer insulator 115 are stacked. The insulating layer including the first interlayer insulator 114 and the second interlayer insulator 115 is provided with the contact holes CH communicating with the drain electrodes D.

The reflecting layer PER extends on the top surface of the interlayer insulator 115 and is not provided in the contact hole CH. Each transmitting layer PET covers the reflecting layer PER and the sidewall of the contact hole CH. Specifically, each transmitting layer PET covers the side surface 114S of the interlayer insulator 114 and the side surface 115S of the second insulating layer 115, and is in contact with the drain electrode D exposed at a position of the contact hole CH. The combination of a portion of the transmitting layer PET in contact with the drain electrode D and a portion of the transmitting layer PET covering the sidewall of the contact hole CH corresponds to the contact portion PEC.

The cover members CV cover the contact portions PEC of the transmitting layers PET. In the example shown, the cover members CV cover the whole portions of the transmitting layers PET positioned in the contact holes CH. Each of the cover members CV covers one contact portion PEC.

The organic layer ORG is provided over the transmitting layers PET and the cover members CV and is further provided over portions of the interlayer insulator 115 which are not covered by the transmitting layers PET and the cover members CV. The counter electrode CE is provided over the organic layer ORG. As shown, in the proximity of each contact hole CH, the organic layer ORG and the cover member CV are interposed between the pixel electrode PE and the counter electrode CE.

In order to form the emitting layers EML1 to EML3 in patterns corresponding to the arrangements of the organic EL elements OLED1 to OLED3, a metal fine mask need be used for evaporation of the emitting materials. In this case, a partition for supporting the fine mask and preventing color mixture is required. In contrast, in the display panel 1, the different luminous colors of the organic EL elements OLED 1 to OLED3 are achieved by the emitting layers EML1 to EML3 each extending over the organic EL elements OLED1 to OLED3. Such emitting layers EML1 to EML3 can be formed without a fine mask. Therefore, this display does not need the partition. As described above, the production process can be simplified by employing the aforementioned structure in the display panel 1.

In the display panel including the partition, the periphery of the pixel electrode is normally covered by the partition. That is, in such a display panel, only a region corresponding to a central portion of the pixel electrode PE contributes to light emission. In contrast, in the display panel 1, the organic layer ORG covers almost the entire electrode pixel PE, and the counter electrode CD covers almost the entire organic layer ORG. Therefore, approximately the whole region corresponding to the pixel electrode PE contributes to light emission. Thus, when the aforementioned structure is employed in the display panel 1, it can broaden the area contributing to light emission, that is, can increase the aperture ratio as compared with when the partition wall is used.

At the positions of the contact holes, defects of the counter electrode and the like are prone to occur. In the display panel in which the partition made of a resin material is formed in a reticular pattern or stripe pattern, moisture can spread to other portions of the partition when moisture enters into a part of the partition through such defects. Thus, the organic EL element can be deteriorated over a broad region.

In contrast, the partition for separating the organic EL elements OLED1 to OLED3 from one another is omitted in the aforementioned display panel 1. Therefore, the spread of moisture via the partition cannot occur in this display panel 1. Thus, the display panel 1 is hard to cause deterioration of the organic EL elements OELD1 to OLED3 which occurs due to the spread of moisture.

Further, in the display panel 1, the cover member CV covers the entire edge surface of the interlayer insulator 115 made of an organic compound. Since the cover member CV is made of an inorganic material, moisture is prevented from entering into the interlayer insulator 115 from the edge surface. Therefore, the spread of moisture through the interlayer insulator 115 does not occur.

Thus, this display panel 1 is hard to cause deterioration of the organic EL elements OLED1 to OLED3 by moisture. The cover member CV may partially cover the edge surface of the interlayer insulator 115 made of the organic compounds at a position of the contact hole CH. Also in this case, entrance of moisture into the interlayer insulator 115 can be prevented although it is not comparable to the case where the cover member CV covers the entire edge surface.

Further, in the display panel 1, there is some possibility that discontinuity occurs in the organic layer ORG due to steps at the position of the contact hole. However, since the contact portion PEC is covered by the cover member CV, the pixel electrode PE and the counter electrode CE does not cause a short circuit even though such discontinuity occurs.

The aforementioned effect can be obtained also in the case where the cover members CV are formed in a reticular pattern correspondingly with the gaps between the adjacent pixel electrodes PE. However, the cover members CV arranged correspondingly with the contact holes CH can be formed more easily as compared with the reticular cover members.

Various modifications can be made to the aforementioned organic EL display. For example, the interlayer insulator 114 may be omitted.

Next, the second embodiment will be described below.

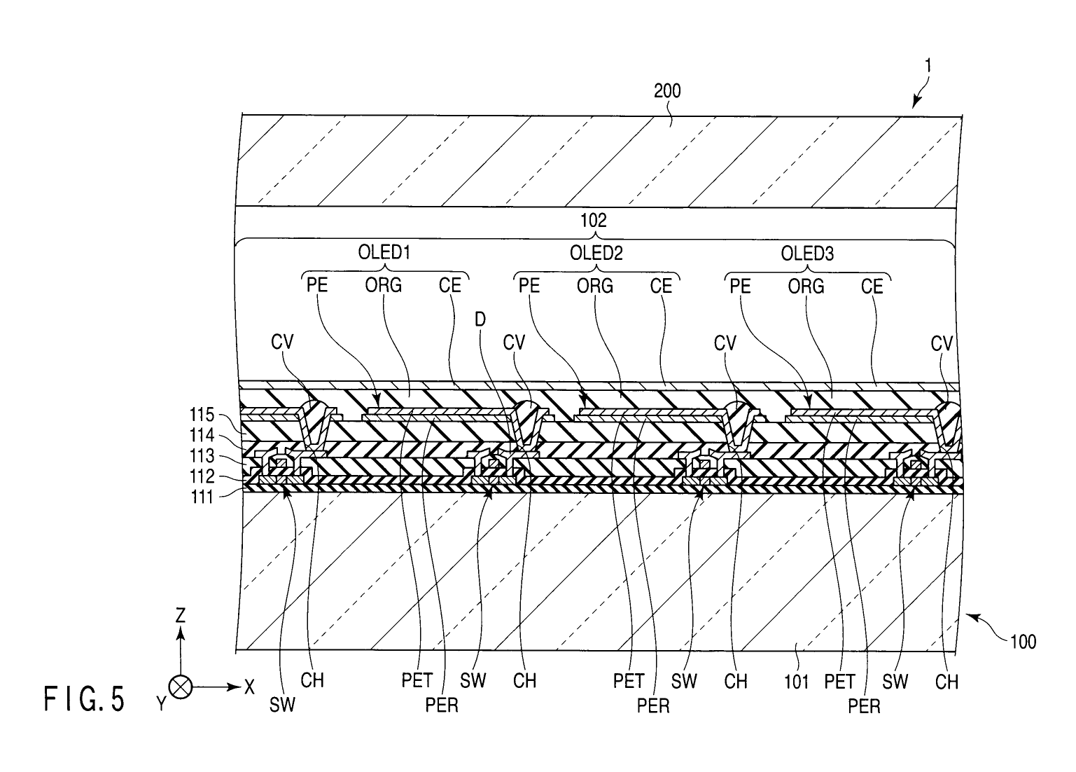

The second embodiment relates to an organic EL display that employs an active matrix driving method. The organic EL display according to the second embodiment is described with reference to FIGS. 5 to 8.

The organic EL display according to the second embodiment is the same as the organic EL display described with reference to FIGS. 1 to 4 except that the following structure is employed.

That is, in this embodiment, the cover members CV not only fill the recessed portions formed by the contact portions PEC in the contact holes but also protrude upward from the recessed portions, as shown in FIG. 5. The top surfaces are convex curved surfaces, that is, dome-shaped surfaces.

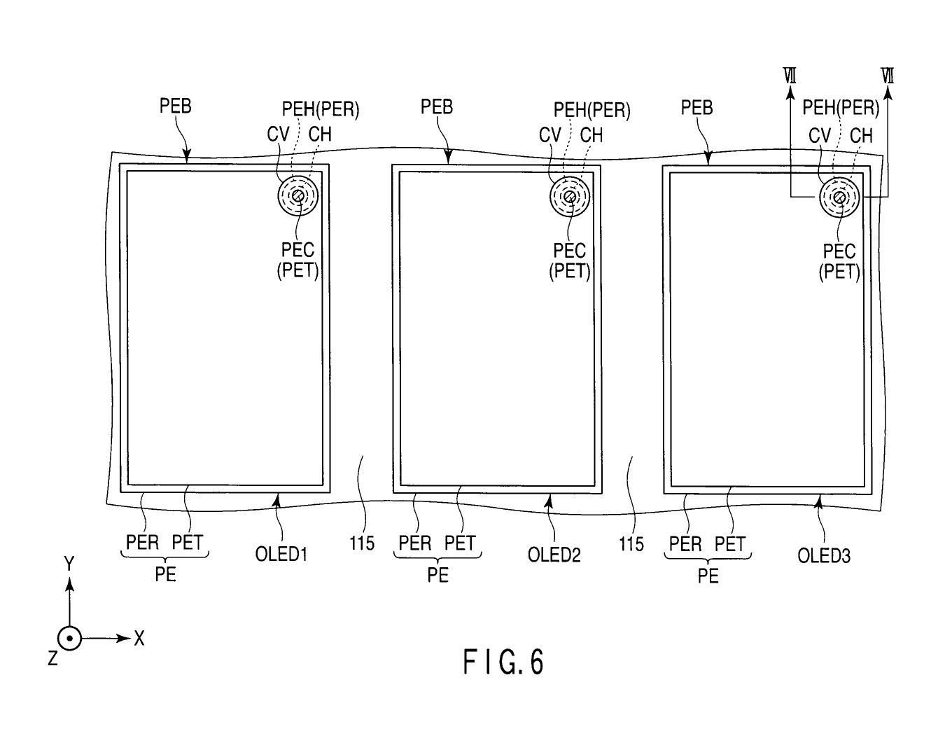

The transmitting layer PET and the reflecting layer PER each have an approximate rectangular shape, as shown in FIG. 6. The contact holes CH each are provided at one of the corners of the pixel electrodes PE. The reflecting layers PER do not exist in the contact holes CH and in the proximity thereof, and form openings PEH having approximate circular shapes.

The cover members CV fill the recessed portions, which the pixel electrodes PE form in the contact holes CH. The cover members CV cover the portions of the transmitting layer PET surrounding the contact holes. Each cover member CV is on the inside of the outline of the transmitting layer PET when observed in the Z direction.

The cover member CV is made of an insulating materials, for example, an organic compounds such as resin. The cover member CV can be formed by, for example, lithography or inkjet printing.

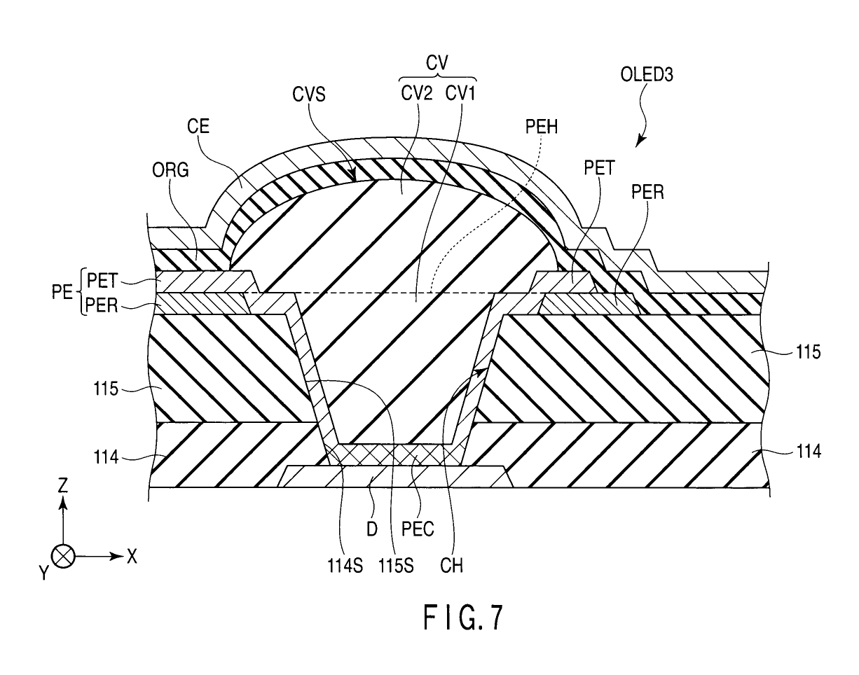

As described above, the cover members CV fill the recessed portions, which the pixel electrodes PE form in the contact holes CH. Specifically, as shown in FIG. 7, each cover member CV includes the first portion CV filling the recessed portion in the contact hole formed by the contact portion PEC and the second portion CV2 protruding upward from this recessed portion.

The surface CVS of the cover member CV is approximately perpendicular to the XY plane in a portion in contact with the pixel electrode PE or in the vicinity thereof. The surface CVS is a convex curved surface. Specifically, the surface CVS has a dome-shaped curved surface which is smoothly curved.

According to the second embodiment, the same effect can be obtained as that obtained by the first embodiment. In the second embodiment, the cover members CV are made of an organic compound. However, the cover members CV do not contact with the interlayer insulator 115 made of an organic compound. Therefore, even though moisture enters into the cover members CV, the moisture does not spread to the interlayer insulator 115.

In the second embodiment, the cover members CV have the surfaces CVS which are convex curved surface. Therefore, the organic layer ORG is excellent in adhesion, and exfoliation of the organic layer ORG is hard to occur. Additionally, discontinuity is hard to occur in the organic layer ORG.

Various modifications can be made to this organic EL display.

For example, the interlayer insulator 114 may be omitted.

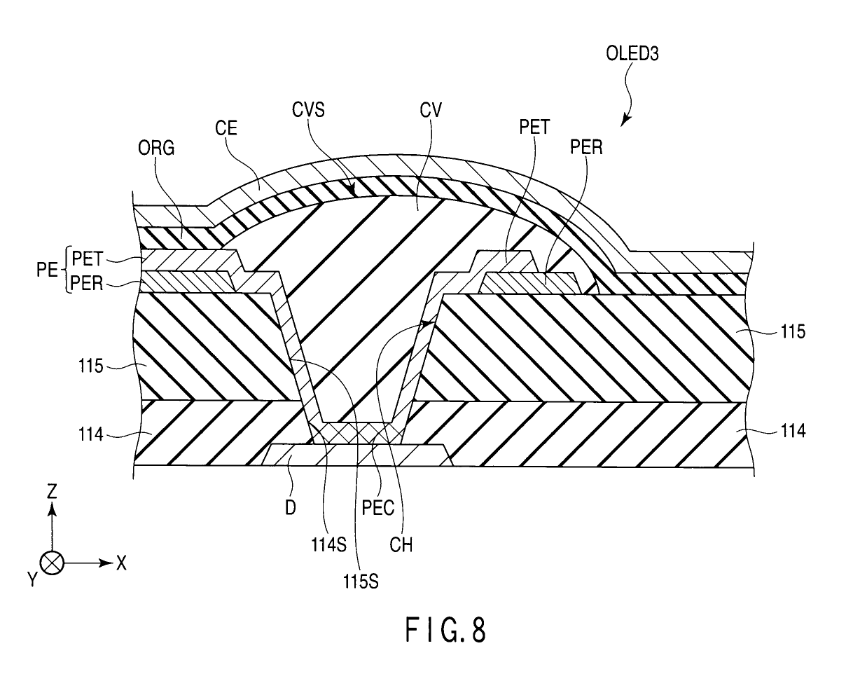

The cover member CV may be in contact with the interlayer insulator 115, as shown in FIG. 8. When the structure shown in FIG. 8 is employed, there is some possibility that the moisture entering into the covering layer CV spreads to the interlayer insulator 115. However, when the contact area between the cover member CV and the interlayer insulator 115 is sufficiently small, the spread of moisture has a small influence on the deterioration of the organic EL elements OLED1 to OLED3.

The surface CVS of the cover member CV can have various shapes. For example, the surface CVS may have a tapered shape other than a dome shape.

The second portion CV 2 of the cover member CV can be omitted. In this case, the surface of the first portion may have a concave shape.

Next, the third embodiment will be described below.

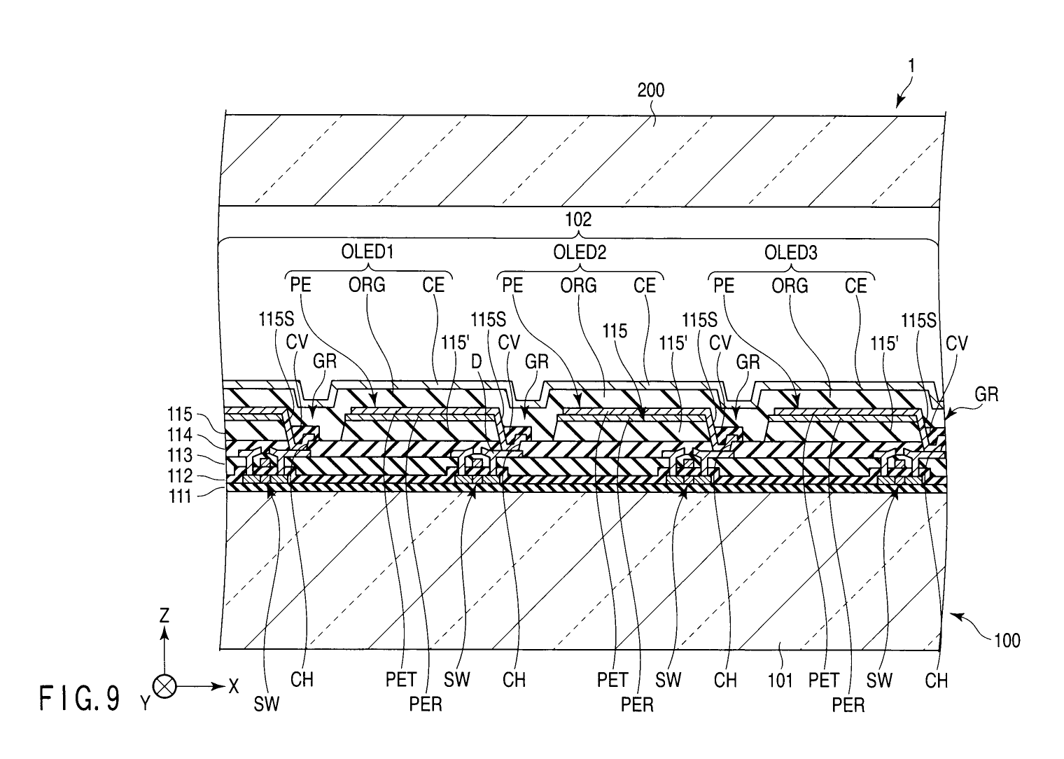

The third embodiment relates to an organic EL display that employs the active matrix driving method. The organic EL display according to the third embodiment is described with reference to FIGS. 9 to 13.

The organic EL display according to the third embodiment is the same as the organic EL display described with reference to FIGS. 1 to 4 except that the following structure is employed.

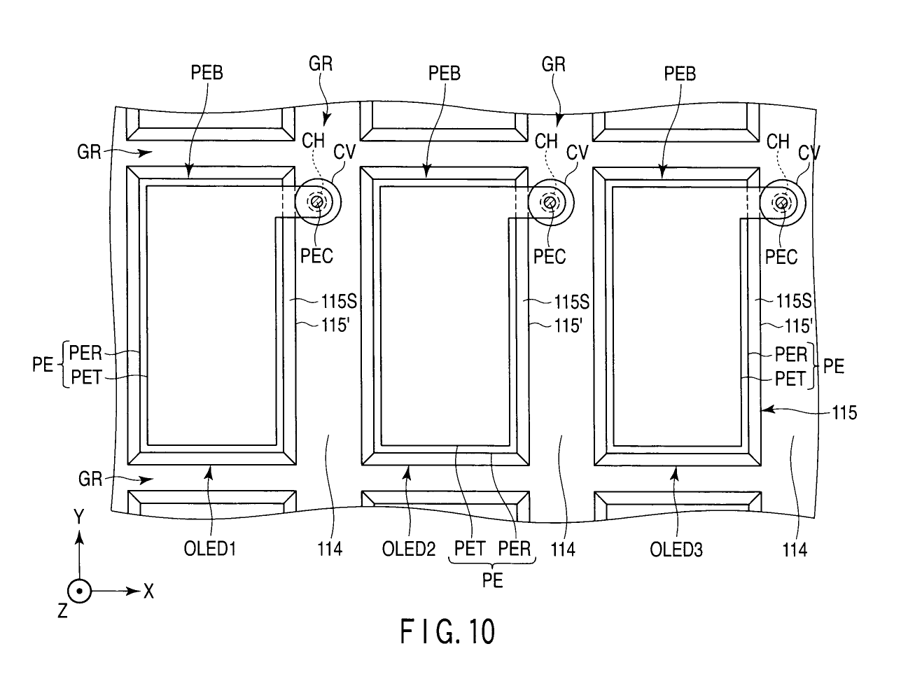

That is, as shown in FIGS. 9 and 10, in this embodiment the interlayer insulator 115 is divided into plural insulating portions 115′ by grooves GR extending in the X direction and grooves GR extending in the Y direction, which form a reticular pattern, such that the contact holes and portions of the interlayer insulator 114 adjacent to the contact holes CH are exposed at bottoms of the grooves.

The reflecting layers PER and the transmitting layers PET have approximate rectangular shapes as shown in FIG. 10. The reflecting layers PER are arranged above the interlayer insulator 115 and do not cover the side surfaces 115S. The electrode bodies PEB are arranged above the insulating portions 115′, respectively. The contact portions PEC cover portions of the side surfaces 115S, the sidewalls of the contact holes CH, and the top surfaces of the drain electrodes D. The contact portions PEC further cover in the grooves GR the portions of the top surface of the interlayer insulator 114 adjacent to the contact holes CH.

The cover members CV each cover the contact portions PEC. Specifically, the cover members CV each fill the recessed portions which the contact portions PEC form in the contact holes CH. The cover members CV are in contact with the interlayer insulator 114 within the grooves GR, and are spaced apart from the interlayer insulator 115. The cover members CV may not be in contact with the interlayer insulator 114.

The insulating material forming the cover members CV is, for example, an organic material. The insulating material may be an inorganic material.

According to the third embodiment, the same effect can be obtained as that obtained by the first embodiment. In the third embodiment, when the cover members are made of an organic compound, there is some possibility that moisture enters into the cover members CV. However, the cover members CV are not in contact with the interlayer insulator 115 made of an organic compound. Therefore, even though moisture enters into the cover members CV, the moisture cannot spread to the interlayer insulator 115.

Further, the interlayer insulator 115 is divided into plural insulating portions 115′ by the grooves GR. The cover members CV do not contribute to the spread of moisture. Therefore, even though moisture enters into an insulating portion 115′, the moisture cannot spread from this insulating portion 115′ to other insulating portions 115′.

Various modifications can be made to this organic EL display.

For example, the interlayer insulator 114 may be omitted.

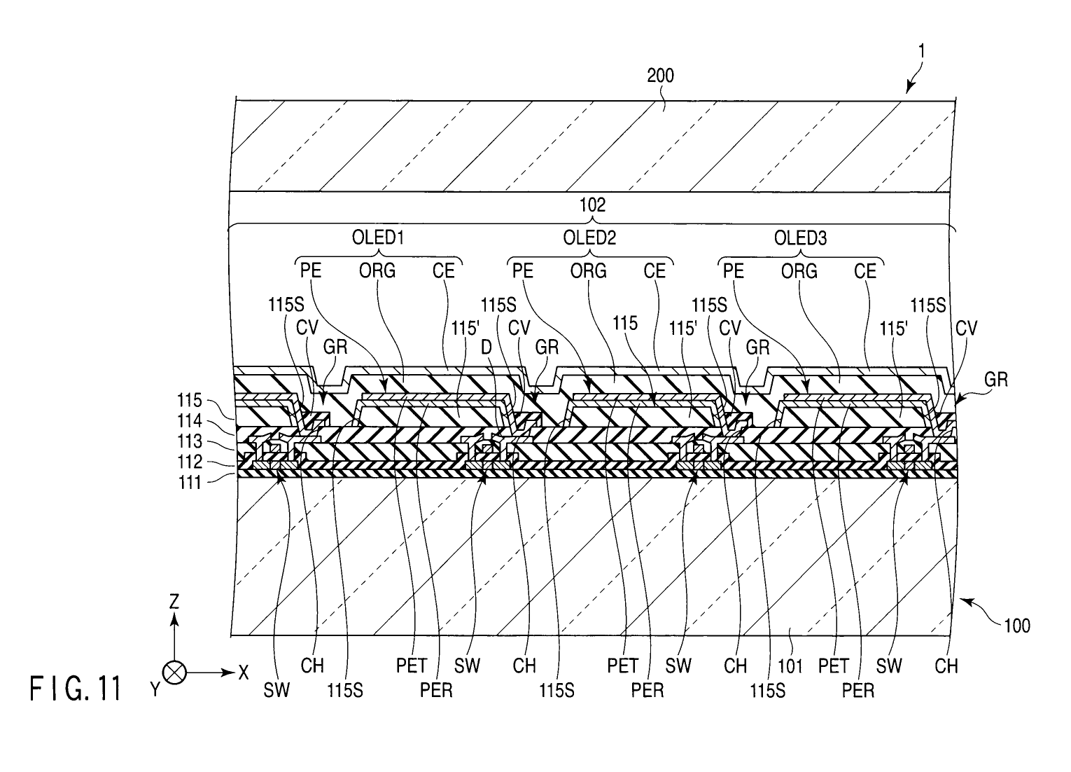

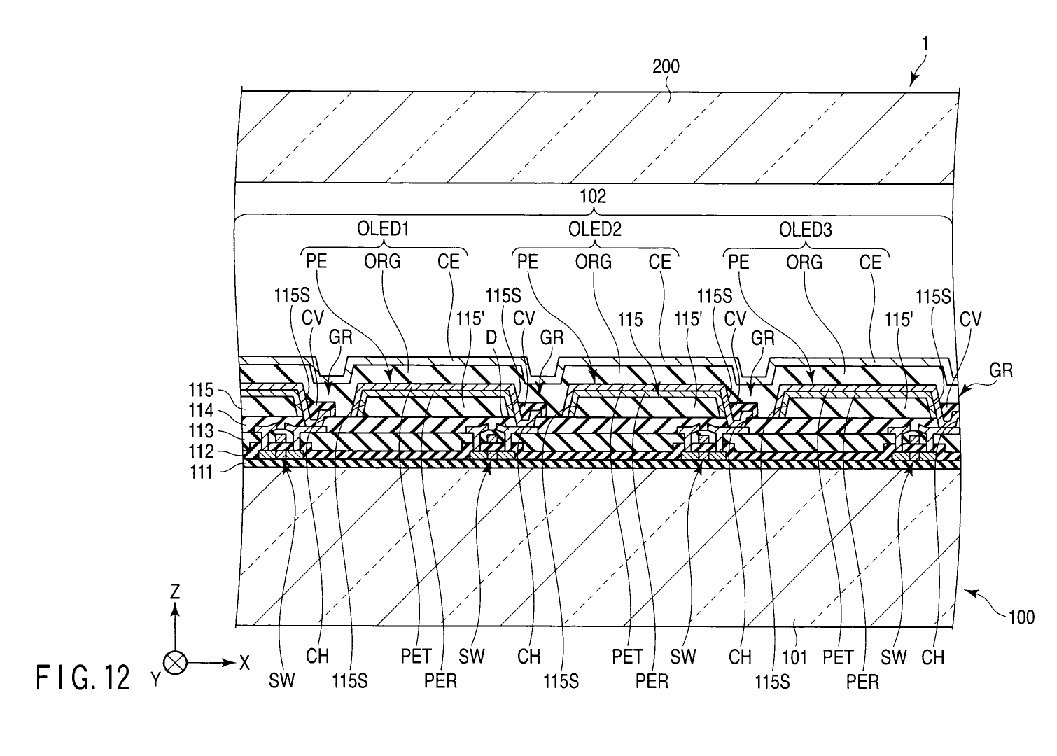

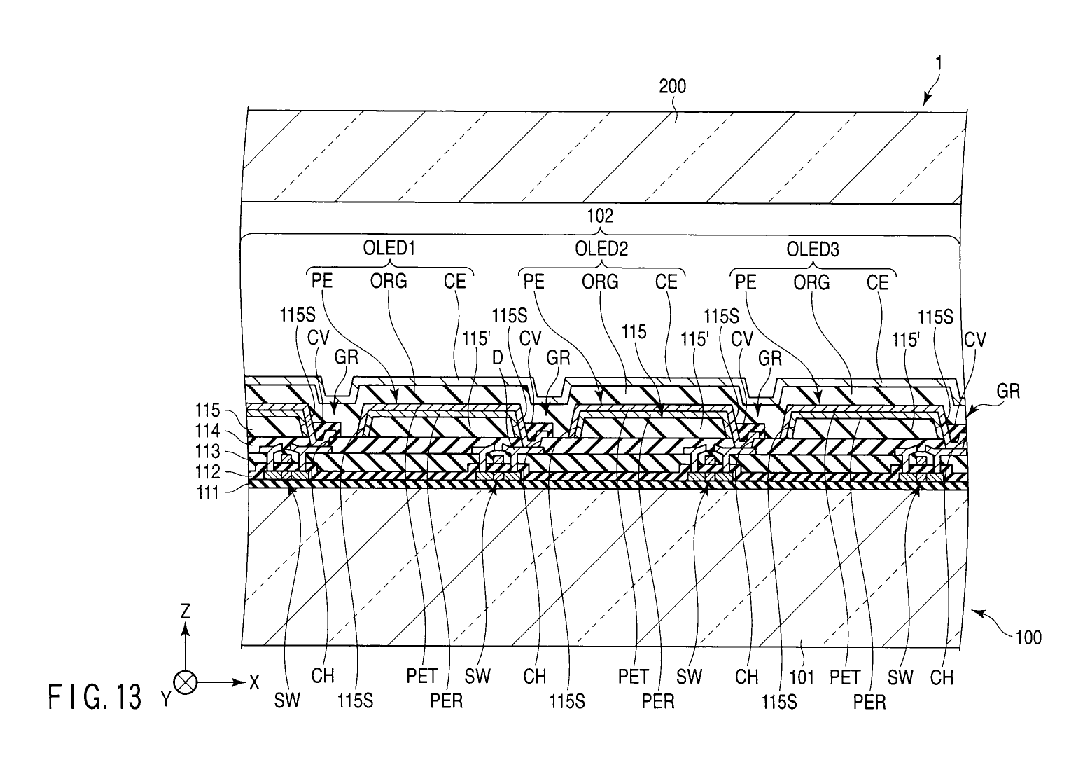

The reflecting layers PER may cover the entire side surfaces 115S as shown in FIG. 11. Alternatively, the transmitting layers PET may cover the entire side surfaces 115S as shown in FIG. 12. Alternatively, the reflecting layer PER and the transmitting layer PET may cover the entire side surfaces 115S as shown in FIG. 13.

When such a structure is employed, the insulating portions 115′ are enclosed with the interlayer insulator 114 and the pixel electrodes PE. In this case, the organic layer ORG cannot be in contact with the interlayer insulator 115.

When such a structure is employed, the same effect as that described with reference to FIGS. 9 and 10 can be obtained. Additionally, in this case, moisture entrance into the interlayer insulator 115 or the spread of moisture from the interlayer insulator 115 to the organic layer ORG is more difficult to occur.

Regarding the organic EL displays according to the first to third embodiments, experiments were carried out to compare resistance of the organic EL elements against moisture.

Eleven glass substrates having a 400 mm×500 mm rectangular shape were prepared as the first mother substrates 1A to 1K. On each of the first mother substrates 1A to 1K, switching elements SW, the first insulating layer 111, second insulating layer 112, third insulating layer 113, and the like were formed. On each of the first mother substrates, the switching elements SW and the like were arranged such that twenty four array substrates 100 each having the active area 102 of a 3.5-inch diagonal size were obtained.

Next, the first interlayer insulator 114 as a passivation layer and the second insulating layer 115 were sequentially formed on the third insulating layer 113 of each of the first mother substrates 1A, 1B, 1D, 1E, 1H, 1I, 1J and 1K. On the other hand, the second interlayer insulator 115 was formed on the third insulating layer 113 of each of the first mother substrate 1C, 1F, and 1G, without formation of a passivation film. An inorganic compound and organic compound were used as a material of the first interlayer insulator 114 and a material of the second interlayer insulator 115, respectively.

In the interlayer insulators 114 and 115 of each of the first mother substrates 1A, 1B, 10, and 1E, contact holes communicating with the switching elements SW were provided. Regarding each of the first mother substrates 1H, 1I, 1J, and 1K, contact holes CH communicating with the switching elements SW were provided in the first interlayer insulator 114, and grooves GR were provided on the second interlayer insulator 115 in a reticular pattern such that the second interlayer insulator 115 was divided into plural insulating portions 115′. The grooves GR were provided such that the contact holes CH were positioned at the bottoms of the grooves GR. Regarding each of the first mother substrates 1C, 1F, and 1G, contact holes CH communicating with the switching elements SW were provided in the second interlayer insulator 115.

Subsequently, pixel electrodes PE were formed on the second interlayer insulators 115 of the first mother substrates 1A to 1K. In the pixel electrodes PE, a two-layer structure was employed. Specifically, reflecting layers PER were formed on the second interlayer insulator 115, and transmitting layers PET made of ITO were formed on the reflecting layers PER. Each of the transmitting layers PET was formed such that the switching element SW and the pixel electrode PE were electrically connected with each other via the contact hole CH.

Regarding the first mother substrate 1H, reflecting layers PER were formed such that each of them was positioned on the inside of the outline of the insulating portion 115′ when observed in the Z direction. Transmissive layers PET were formed such that a portion of each transmitting layer PET other than that for electrically connecting the electrode body PEB to the switching element SW was positioned on the inside of the outline of the insulating portion 115′ when observed in the Z direction. That is, in the first mother substrate 1H the structure described with reference to FIGS. 9 and 10 was employed.

Regarding the mother substrate 1I, reflecting layers PER were formed such that each insulating portion 115′ was positioned on the inside of the outline of the reflecting layer PER when observed in the Z direction. Transmissive layers PET were formed such that a portion of the transmitting layer PET other than that for electrically connecting the electrode body PEB to the switching element SW was positioned on the inside of the outline of the insulating portion 115′ when observed in the Z direction. That is, in the first mother substrate 1I, the structure described with reference to FIG. 11 was employed.

Regarding the first mother substrate 1J, reflecting layers PER were formed such that each of them was positioned on the inside of the outline of the insulating portion 115′ when observed in the Z direction. Transmissive layers PET were formed such that each insulating portion 115′ was positioned on the inside of the outline of the transmitting layer PET when observed in the Z direction. That is, in the first mother substrate 1J the structure described with reference to FIG. 12 was employed.

Regarding the first mother substrate 1K, reflecting layers PER were formed such that each of them was positioned on the inside of the outline of the insulating portion 115′ when observed in the Z direction. Transmissive layers PET were formed such that each insulating portion 115′ was positioned on the inside of the outline of the transmitting layer PET when observed in the Z direction. That is, in the first mother substrate 1K, the structure described with reference to FIG. 13 was employed.

Next, on the first mother substrate 1A, a partition having a thickness of 2 μm was formed in a reticular pattern such that the partition is interposed between the adjacent pixel electrodes PE. Resin was used as a material of this partition. The partition was formed such that it covered the contact portions PEC.

On the other hand, regarding the first mother substrates 1B to 1K, contact portions PEC were covered by cover members CV without formation of a partition.

Specifically, regarding each of the first mother substrates 1B and 1C, a thin film made of silicon nitride (SiN) was formed by a plasma CVD method, and was patterned into an islands structure, resulting in the cover members CV. That is, to the first mother substrate 1B, the structure described with reference to FIGS. 1 to 4 was employed. To the first mother substrate 1C, the same structure as that described with reference to FIGS. 1 to 4 was employed except that the first interlayer insulator 114 was omitted.

Regarding each of the first mother substrates 1D, 1E, 1F, and 1G, cover members CV made of resin were formed by inkjet printing. Here, regarding each of the first mother substrates 1D and 1F, cover members CV were formed such that they were in contact with the second interlayer insulator 115. That is, in the first mother substrate 1D, the structure described with reference to FIG. 8 was employed. In the first mother substrate 1F, the same structure as that described with reference to FIG. 8 was employed except that the first interlayer insulator 114 was omitted. Regarding each of the first mother substrates 1E and 1G, cover members CV were formed such that each of them was positioned on the inside of the outline of the pixel electrode PE when observed in the Z direction. That is, in the first mother substrate 1E, the structure described with reference to FIGS. 5 to 7 was employed. In the first mother substrate 1G, the same structure as that described with reference to FIGS. 5 to 7 was employed except that the first interlayer insulator 114 was omitted.

Regarding each of the first mother substrates 1H, 1I, 1J, and 1K, cover members CV made of resin were formed by inkjet printing. In these cover members CV, the structure described with reference to FIGS. 9 and 10 was employed.

Subsequently, with use of a deposition apparatus which performs vacuum evaporation by an electrical resistance heating method, a hole-transporting layer, emitting layers, an electron-transporting layer and a counter electrode were sequentially formed on the first mother substrate 1A. As a material of the counter electrode CE, magnesium and silver were used. These emitting layers were formed with use of a high precision metal mask. Specifically, an emitting layer emitting red light, an emitting layer emitting green light, and an emitting layer emitting blue light were formed for the organic EL elements OLED1, OLED2, and OLED3, respectively.

On each of the first mother substrates 1B to 1K, emitting layers, an electron-transporting layer, electron injection layer, and counter electrode CE were sequentially formed with use of the deposition apparatus which performs vacuum evaporation by the electrical resistance heating method.

Specifically, without use of a metal mask, a hole-transporting layer and a red emitting layer including the first dopant emitting red light were formed. Subsequently, each of the first mother substrates 1B to 1K was taken out from the deposition apparatus, and the regions of the red emitting layer in which organic EL elements OLED2 and OLED3 should be formed were irradiated with ultraviolet having a main wavelength of 365 nm via a photo mask. Thus, light emission of the first dopant included in these regions was inhibited.

Next, each of the first mother substrates 1B to 1K was put back into the deposition apparatus, and then a green emitting layer including the second dopant emitting green light was formed on the red emitting layer without use of a metal mask. Subsequently, each of the first mother substrates 1B to 1K were taken out from the deposition apparatus, and the regions of the green color emitting layer in which the third organic EL elements OLED3 should be formed were irradiated with ultraviolet having a main wavelength of 365 nm via a photo mask. Thus, light emission of the second dopant included in these regions was inhibited.

After that, each of the first mother substrates 1B to 1K was taken out from the deposition apparatus, and then a blue emitting layer including the third dopant emitting blue light was formed on the green emitting layer. Subsequently, on the blue color emitting layer, an electron-transporting layer, electron injection layer, and counter electrode CE were sequentially formed. As a material of the counter electrode CE, magnesium and silver were used.

Next, as the second mother substrates, eleven glass substrates were prepared. Each of the second mother substrates had sufficient size for obtaining twenty four sealing substrates 200.

On each of the second mother substrates, an ultraviolet curing resin as a sealing material was applied with use of a dispenser such that twenty four frames were formed. Subsequently, these second mother substrates and the first mother substrates 1A to 1K were bonded together in a vacuum chamber such that ultraviolet curing resin was interposed therebetween. Then, the ultraviolet resin was cured by ultraviolet irradiation. Between the first and second mother substrates, no drying agent was placed.

Then, each of the combinations of first and second mother substrates was broken into twenty four display panels 1. Signal supply sources were further mounted to each of the display panels 1.

A group including twenty four display panels 1 and obtained using the first mother substrate 1A is referred to as group A. Similarly, groups each including twenty four display panels and obtained using the first mother substrates 1B to 1K are referred to as groups 1B to 1K, respectively.

Subsequently, all the display panels of the groups 1A to 1K were left in a high temperature and high humidity bath (temperature 85° C., relative humidity 85%), and they were taken out therefrom every time when the predetermined time passed and were subjected to a lighting test. In the lighting test, the number of the panels in which dark spots occurred was counted by observing the screens while each of the display panel was kept on. The results are summarized in Table 1.

TABLE 1

| | | | | Number of display panels in which dark spot | | | | | | | | |
|---|---|---|---|---|---|---|---|---|---|---|---|---|
| | 1st interlayer | Cover member | | defect occurred | | | | | | | | |
| Group | insulator | Material | Structure | 10 h | 15 h | 20 h | 25 h | 30 h | 35 h | 40 h | 45 h | 50 h |
| 1A | Present | Organic | Partition | 0 | 0 | 7 | 23 | 24 | 24 | 24 | 24 | 24 |
| 1B | Present | Inorganic | Islands | 0 | 0 | 0 | 0 | 1 | 4 | 10 | 20 | 24 |
| 1C | Absent | Inorganic | Islands | 0 | 0 | 0 | 0 | 1 | 5 | 13 | 21 | 24 |
| 1D | Present | Organic | Islands *6) | 0 | 0 | 0 | 0 | 2 | 7 | 15 | 22 | 24 |
| 1E | Present | Organic | Islands *7) | 0 | 0 | 0 | 0 | 0 | 2 | 2 | 7 | 16 |
| 1F | Absent | Organic | Islands *6) | 0 | 0 | 0 | 0 | 1 | 6 | 13 | 22 | 24 |
| 1G | Absent | Organic | Islands *7) | 0 | 0 | 0 | 0 | 0 | 1 | 2 | 6 | 15 |
| 1H *1) *2) | Present | Organic | Islands | 0 | 0 | 0 | 0 | 0 | 0 | 3 | 5 | 7 |
| 1I *1) *3) | Present | Organic | Islands | 0 | 0 | 0 | 0 | 0 | 0 | 0 | 2 | 5 |
| 1J *1) *4) | Present | Organic | Islands | 0 | 0 | 0 | 0 | 0 | 0 | 0 | 2 | 4 |
| 1K *1) *5) | Present | Organic | Islands | 0 | 0 | 0 | 0 | 0 | 0 | 0 | 1 | 3 |

Notes:
*1) Grid pattern of grooves was formed in 2nd interlayer insulator.
*2) Reflecting and transmitting layers were formed not to extend beyond outlines of insulating portions.
*3) Reflecting layers were formed to extend beyond outlines of insulating portions.
*4) Transmitting layer was formed to extend beyond outlines of insulating portions.
*5) Reflecting and transmitting layers were formed to extend beyond outlines of insulating portions.
*6) Cover members were in contact with 2nd interlayer insulator.
*7) Cover members were spaced apart from 2nd interlayer insulator.

Each of the display panels of group 1A included the interlayer insulator 114 and the reticular partition, but did not include cover members CV. Regarding group 1A, after 20 hours, 25 hours, and 30 hours, dark spots occurred in seven display panels, twenty three display panels, and all the display panels, respectively.

Each of the display panels of group 1B did not include the partition but included the first interlayer insulator 114 and the cover members CV made of an inorganic compound. Regarding group 1B, after 30 hours, 35 hours, 40 hours, 45 hours, and 50 hours, dark spots occurred in one display panel, four display panels, ten display panels, twenty display panels, and all the display panels, respectively.

Each of the display panels of group 1C did not include the partition and the first interlayer insulator 114 but included the cover members CV made of an inorganic compound. Regarding group 1C, after 30 hours, 35 hours, 40 hours, 45 hours, and 50 hours, dark spots occurred in one display panel, five display panels out of twenty four display panels, thirteen display panels, twenty one display panels, and all the display panels, respectively.

As described above, when the partition is omitted and the cover members CV made of an inorganic compound are provided, deterioration of organic EL elements due to moisture could be suppressed regardless presence or absence of the first interlayer insulator 114.

Each of the display panels of group 1D included the first interlayer insulator 114 and the cover members made of an organic compound, and the cover members CV were in contact with the second interlayer insulator 115. Regarding group 1D, after 30 hours, 35 hours, 40 hours, 45 hours, and 50 hours, dark spots occurred in two display panel, seven display panels, fifteen display panels, twenty two display panels, and all the display panels, respectively.

Each of the display panels of group 1E included the first interlayer insulator 114 and the cover members CV made of an organic compound, and the cover members CV were not in contact with the second interlayer insulator 115. Regarding group 1F, after 35 hours, 45 hours, and 50 hours, dark spots occurred in two display panel, seven display panels, and sixteen display panels, respectively.

Each of the display panels of group 1F did not include the first interlayer insulator 114 but included the cover members CV made of an organic compound, and the cover members CV were in contact with the second interlayer insulator 115. Regarding group 1F, after 30 hours, 35 hours, 40 hours, 45 hours, and 50 hours, dark spots occurred in one display panel, six display panels, thirteen display panels, twenty two display panels display panels, and all the display panels, respectively.

Each of the display panels of group 1G did not include the first interlayer insulator but included the cover members CV made of an organic compound, and the cover members were not in contact with the second interlayer insulator 115. Regarding group 1G, after 35 hours, 40 hours, 45 hours, and 50 hours, dark spots occurred in one display panel, two display panels, six display panels, and fifteen display panels, respectively.

As described above, when a partition is omitted and the cover members CV made of an organic compound are provided, deterioration of organic EL elements due to moisture could be suppressed regardless of presence or absence of the first interlayer insulator 114 as a passivation film. In particular, in the display panels of groups 1E and 1G in which the cover members CV were not in contact with the second interlayer insulator 115, the spread of moisture was inhibited and deterioration of the organic EL elements could be suppressed as compared with the display panels of groups 1D and 1F in which the cover members CV were in contact with the second interlayer insulator 115.

In the display panels of group 1H, most of the side surfaces 115S of each insulating portion 115′ were not covered by the reflecting layer PER or transmitting layer PET. Regarding group 1H, after 40 hours, 45 hours, and 50 hours, dark sport occurred in three display panels, five display panels, and seven display panels, respectively.

In the display panels of group 1I, the side surfaces 115S of each insulating portion 115′ were covered by the reflecting layer PER. Regarding group 1I, after 45 hours and 50 hours, dark spots occurred in two display panels and five display panels, respectively.

In the display panels of group 1J, the side surfaces 115S of each insulating portion 115′ were covered by the transmitting layer PET. Regarding group 1J, after 45 hours and 50 hours, dark spots occurred in two display panels and four display panels, respectively.

In the display panels of group 1K, the side surfaces 115S of each insulating portion 115′ were covered by the two-layer structure of the reflecting layer PER and the transmitting layer PET. Regarding group 1K, after 45 hours and 50 hours, dark spots occurred in one display panels and three display panels, respectively.

As described above, in each display panel of groups 1H to 1K, the partition was omitted, the second interlayer insulator 115 was divided into plural insulating portions 115′ by the grooves GR, and the cover members CV made of an organic compound were provided. In such display panels, the spread of moisture was inhibited and deterioration of the organic EL elements could be suppressed as compared with the display panels of groups 1A to 1G.

Further, in particular in the display panels of groups 1I to 1K in which the side surfaces 115S of each insulating portion 115′ were covered by at least one of the reflecting layer PER and transmitting layer PET, the spread of moisture was inhibited and deterioration of the organic EL elements could be suppressed as compared with the display panels of group 1H in which the side surfaces 115S of each insulating portion 115′ were not covered by the pixel electrode PE.

Next, the fourth embodiment will be described below.

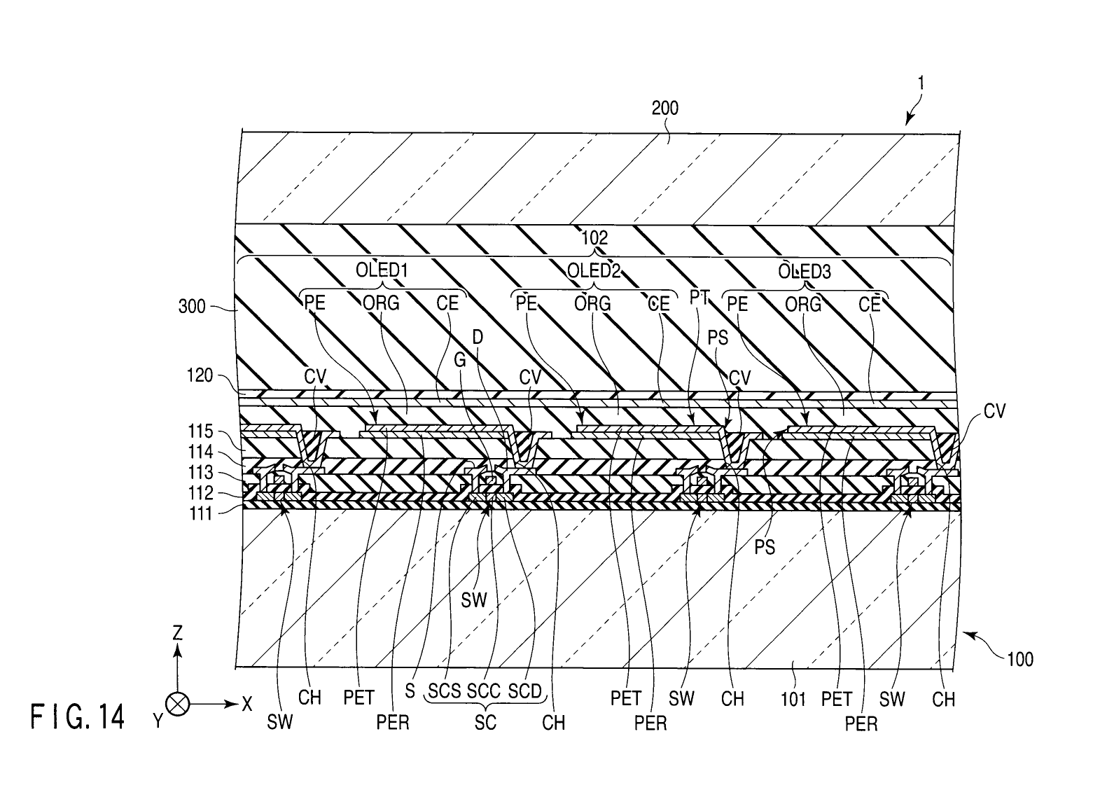

The fourth embodiment relates to an organic EL display that employs the active matrix driving method. The organic EL display according to the fourth embodiment is described with reference to FIGS. 14 to 16.

The organic EL display according to the fourth embodiment is the same as the organic EL display described with reference to FIGS. 1 to 4 except that the following structure is employed.

That is, in this embodiment, the sealing layer 120 is provided over the counter electrode as shown in FIG. 14. The sealing layer 120 extends all over the active area 102. Namely, the sealing layer 120 extends over the organic EL elements OLED1 to OLED3. The sealing layer 120 is made of a material, which has a light-transmitting property and is difficult for moisture to permeate, for example, an inorganic compound such as silicon nitride and silicon oxynitride. Such a sealing layer 120 serves as a moisture barrier film which prevents entrance of moisture into the organic EL elements OELD1 to OLED3.

Between the array substrate 100 and the sealing substrate 200, a sealing member (not shown) and the resin layer 300 are interposed.

The sealing member has, for example, a frame shape. The sealing member is made of, for example, an organic material such as ultraviolet curing resin.

The filler layer 300 fills the space which is surrounded by the array substrate 100, sealing substrate 200, and sealing member. Typically, the filler layer 300 fills the aforementioned space without leaving a gap.

The filler layer 300 is formed from, for example, an organic material such ultraviolet curing resin. Here, ultraviolet is an electromagnetic wave having a wavelength ranging from about 200 nm to about 400 nm.

The sealing member and filler layer 300 bond the array substrate 100 and the counter substrate 200 together. The raw material of the sealing member, for example, ultraviolet curing resin, is applied to, for example, the main surface of either one of the array substrate 100 and the counter substrate 200 in a frame shape prior to bonding the array substrate 100 and the counter substrate 200 together. The raw material of the sealing member may be applied on the array substrate 100 or the counter substrate 200 after curing this frame made of ultraviolet curing resin. Alternatively, the raw materials of the sealing member may be applied to the array substrate 100 or the counter substrate 200 before curing the frame made of the ultraviolet curing resin.

Each of the cover members CV fills the recessed portion which the contact portion PEC forms in the contact hole CH. That is, the cover member CV is a filling member here.

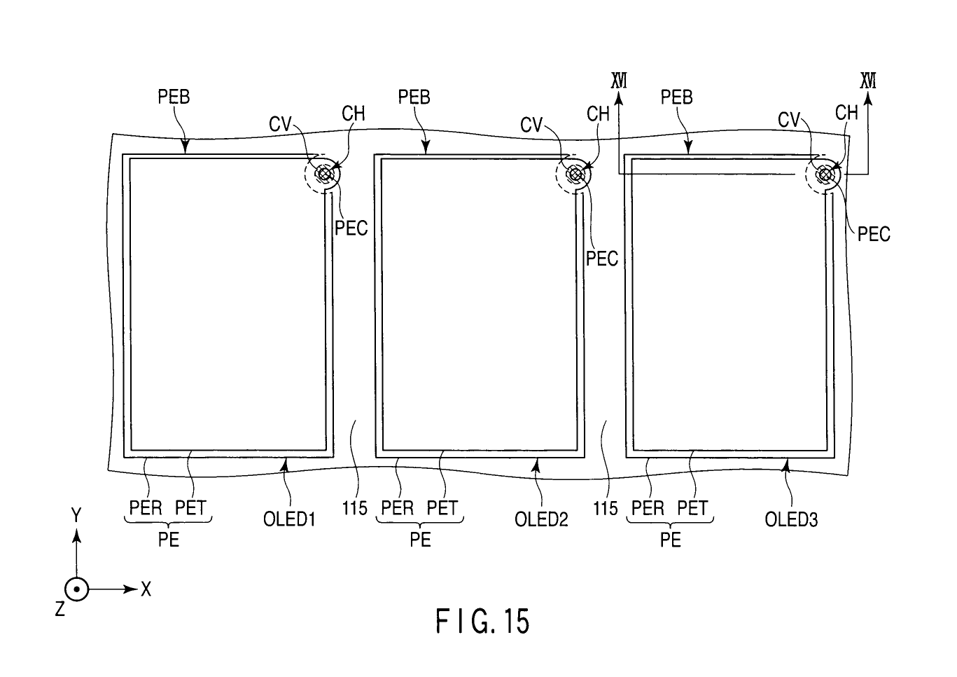

Each cover member CV is positioned on the inside of the outline of the transmitting layer PET when observed from the Z direction, as shown in FIG. 15. The cover members CV are not in contact with the second interlayer insulator 115. As shown in FIGS. 14 to 16, the cover members CV are provided, for example, only in the aforementioned recessed portions.

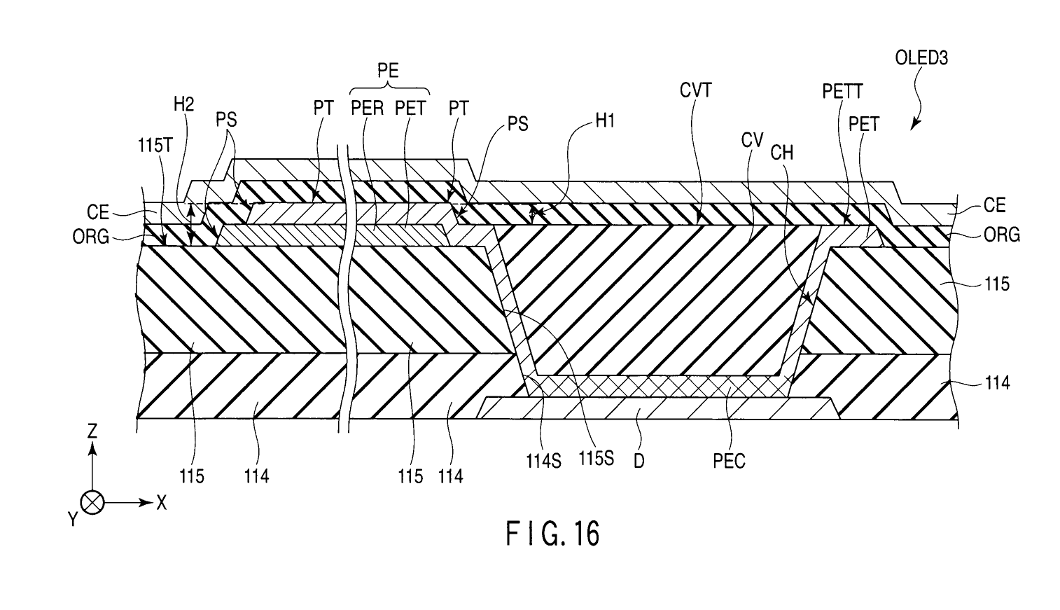

As shown in FIG. 16, the top surface CVT of the cover member CV is approximately flat. The top surface CVT is almost flush with the top surface PETT of the portion positioned above the second interlayer insulator 115 of the transmitting layer PET. That is, the cover member CV makes the surface of the pixel electrode PE approximately flat.

The cover member CV is made of an insulating material, for example, an organic material such as resin. The cover member CV can be formed by, for example, lithography or inkjet printing.

According to the fourth embodiment, the same effect can be obtained as that obtained by the first embodiment.

Further, according to the fourth embodiment, the partition is omitted and the recessed portions are made flat at positions of the contact holes CH. Therefore, as compared with the case where the partition is provided, exfoliation of films of the organic EL elements OLED1 to OLED3, in particular, of the organic layer ORG and counter electrode CE can be suppressed. This point will be described more specifically below.

When a partition of a reticular pattern is provided, stress is concentrated on films at positions corresponding to edge portions of the partition or portions having large gaps. Therefore, for example, the films are sometimes exfoliated at the edge portions. In particular, adhesion of the organic layer ORG and the counter electrode CE is relatively weak, and the counter electrode CE is easy to exfoliate. A cause of the stress is, for example, difference of thermal expansion coefficient from the sealing layer 120, resin layer 300, and the like; heat shrinkage upon curing of the resin layer 300; and bending stress caused by bending the array substrate 100. Such exfoliation of films is particularly serious when the display panel 1 is a large scale panel.

In this embodiment, the partition is omitted, and the recessed portions which the pixel electrodes PE form at positions of the contact hole CH are made flat by the cover members CV. Thus, unevenness of the groundwork of the organic layer ORG and the counter electrode CE is reduced, and concentration of stress can be eased.

Specifically, the height of the partition is micrometers, for example, about 2 μm. In contrast, the height difference H1 between the top surface PT of the pixel electrode PE and the top surface CVT of the cover member CV; or the height difference H2 between the top surface PT and the top surface 115T of the groundwork of the pixel electrode, that is, the second interlayer insulator 115 is, for example, 0.2 μm or less. In the example shown, the top surface PT of the pixel electrode PE is not the top surface PETT of a portion of the transmitting layer PET which is positioned on the interlayer insulator 115, but is a top surface of a portion of the transmitting layer PET positioned on the reflecting layer PER.

Therefore, according to this embodiment, exfoliation of the organic layer ORG and the counter electrode CE can be suppressed. Further, according to this embodiment discontinuity in the organic layer ORG dues to the unevenness can be suppressed. Additionally, according to this embodiment cracks in the counter electrode CE can be also suppressed.

Further, according to this embodiment the cover members CV can be formed by, for example, inkjet printing. Therefore, as compared with the case where the partition is formed by lithography, it enables shorter production time, simpler production process, and less production cost.

Since the partition is omitted, concentration of stress is eased and exfoliation of films can be suppressed even though the display panel 1 is a flexible panel in which bending stress is applied to the array substrate 100.

Various modifications can be made to the aforementioned organic EL display. For example, the interlayer insulator 114 may be omitted.

Next, the fifth embodiment will be described below.

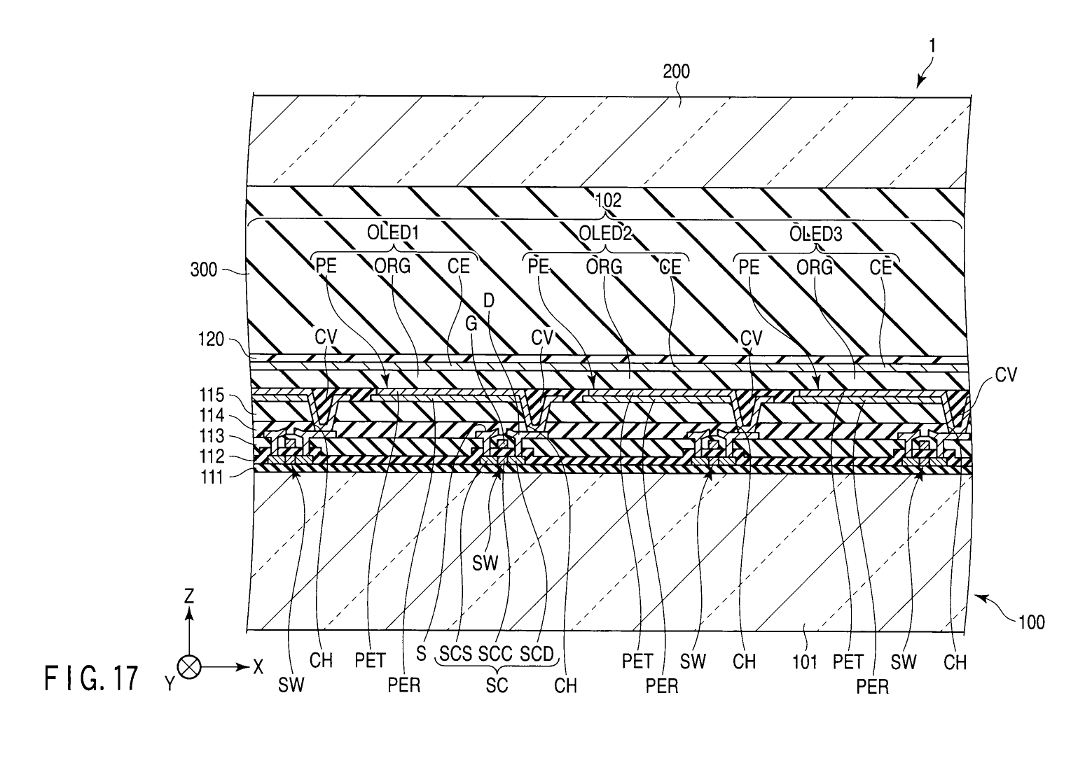

The fifth embodiment relates to an organic EL element display that employs the active matrix driving method. The organic EL display of the fifth embodiment is described with reference to FIGS. 17 to 19.

The organic EL display of the fifth embodiment is the same as the organic EL element described with reference to FIGS. 14 to 16 except that the following structure is employed.

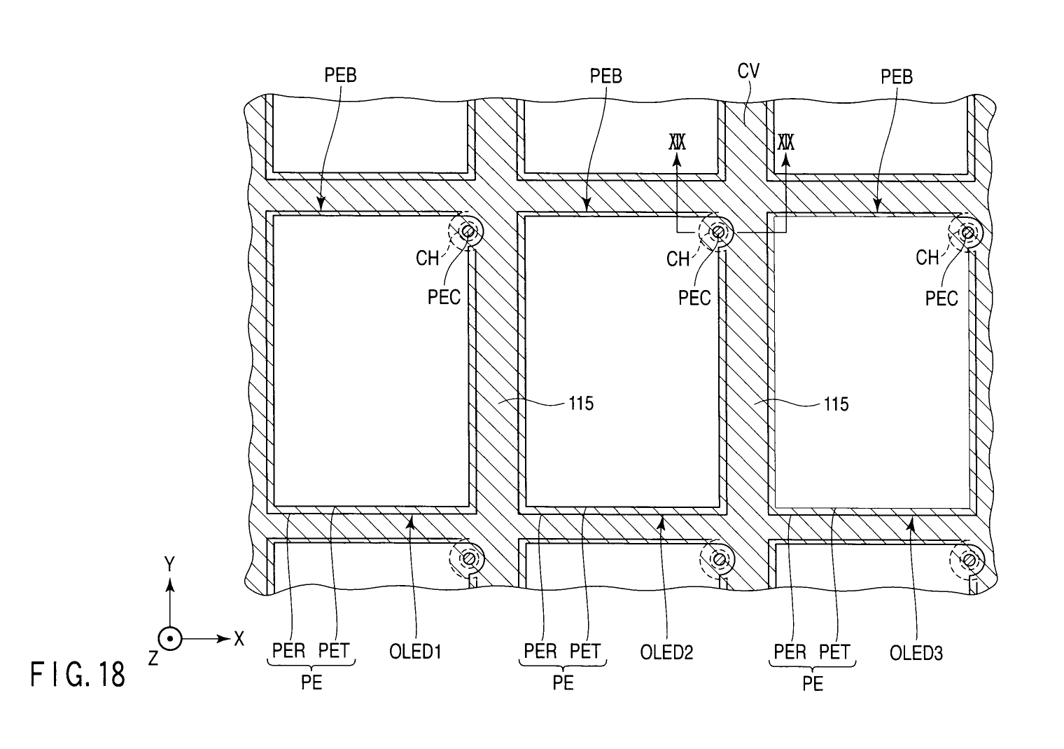

That is, in this embodiment, the cover members CV fill not only the recessed portions which the pixel electrodes form in the contact holes CH but also the gaps between the pixel electrodes as shown in FIG. 17. As a result, the cover members CV form a reticular pattern as shown in FIG. 18.

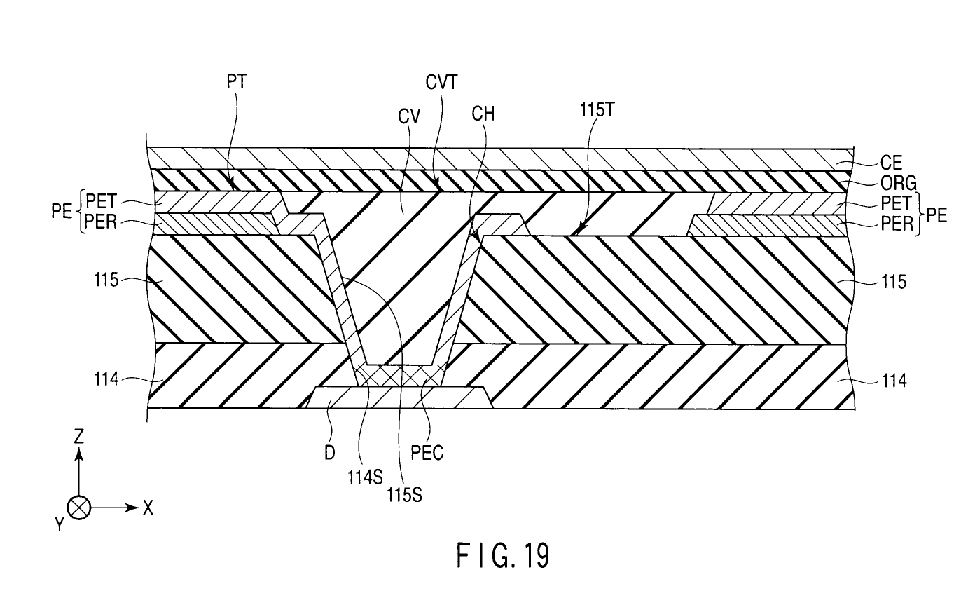

As shown in FIG. 19, the top surface of the cover member CV is approximately flat. The top surface CVT is approximately flush with the top surface of the pixel electrode PE, specifically, with the top surface PT of a portion of the transmitting layer PET positioned above the reflecting layer PER.

The cover member CV is made of an insulating material, for example, an organic compound such as resin. The cover member CV can be formed by, for example, lithography or inkjet printing.

The organic layer ORG covers the transmitting layers PET and the cover members CV. The organic layer ORG are not in contact with the second interlayer insulator 115.

According to the fifth embodiment, the same effect can be obtained as that obtained by the fourth embodiment.

Further, according to the fifth embodiment, as compared with the fourth embodiment, the groundwork of the organic layer ORG and the counter electrode CE can be made more flat. Therefore, exfoliation of the organic layer ORG and counter electrode CE is more difficult to occur.

Various modifications can be made to the aforementioned organic EL display. For example, the interlayer insulator 114 may be omitted.

Experiments were carried out to compare resistance of the organic EL elements against moisture for the organic EL display according to the fourth and fifth embodiments.

As the insulating substrates 101, twenty glass substrates having a 400 mm×500 mm rectangular shape of were prepared. On each of these insulating substrates 101, switching elements SW, the first insulating layer 111, second insulating layer 112, third insulating layer 113, and the like were formed. On each of the insulating substrates 101, the switching elements SW and the like were arranged such that one array substrate 100 having the active area 102 of a 21 type diagonal size was obtained. These insulating substrates 101 were classified into four groups 2A to 2D each including five insulating substrates 101.

Regarding each of the insulating substrates 101 of groups 2A, 2B, and 2D, the first interlayer insulating 114 as a passivation film and the second interlayer insulator 115 were then formed sequentially on the third insulating layer 113. On the other hand, regarding each of the insulating substrates 101 of group 2C, the second interlayer insulator 115 was formed on the third insulating layer 113 without formation of the passivation film. An inorganic compound and organic compound were used as materials of the first interlayer insulator 114 and the second interlayer insulator 115, respectively. The interlayer insulators 114 and 115 were formed in film thickness of 300 nm and 2 μm, respectively.

Regarding each of the insulating substrates 101 of groups 2A, 2B, and 2D, contact holes CH communicating with the switching elements SW were provided in the interlayer insulators 114 and 115. Regarding each of the insulating substrates 101 of group 2C, contact holes CH communicating with the switching elements SW were provided in the second interlayer insulator 115.

Subsequently, regarding each of the insulating substrates 101 of groups 2A to 2D, pixel electrodes PE were formed on the second interlayer insulator 115. A two-layer structure was employed in the pixel electrodes. Specifically, the reflecting layers PER were formed on the second interlayer insulators 115, and transmitting layers PET made of ITO were formed on the reflecting layers PER. Each of the transmitting layer PET was formed such that the switching elements SW and pixel electrodes PE were electrically connected via the contact holes CH.

Regarding each of the insulating substrates 101 of groups 2A, 2B, and 2C, the film thickness of the reflecting layers PER and that of the transmitting layers PET were 80 nm and 50 nm, respectively. Regarding the insulating substrates 101 of group 2D, the film thickness of the reflecting layers PER and that of the transmitting layers PET were 200 nm and 100 nm, respectively.

Regarding each of the insulating substrates 101 of group 2A, a partition having thickness of 2 μm was formed such that the partition was interposed between the adjacent pixel electrodes PE. As a material of the partition, resin was used. The partition was formed such that it covered the contact portions PEC. The step height of the top surface of the partition with respect to the top surfaces of the pixel electrodes PE was 2.0 to 2.1 μm.

Regarding each of the insulating substrates 101 of groups 2B and 2C, the recessed portions positioned at the contact holes CH were filled with the cover members CV without formation of the partition. Specifically, the cover members CV were formed by supplying thermosetting resin into the recessed portions by inkjet printing and heat-curing it with a heat treatment at 150° C. for 2 hours. These cover members CV were not in contact with the second interlayer insulating layers 115. Regarding each of the insulating substrates 101 of group 2B, the step height of the surface, that is, the step height of the top surface of the pixel electrode PE with respect to the top surface of the cover member CV or the step height of the top surface of the pixel electrode with respect to the top surface of the second insulating layer 115 was 0.19 to 0.20 μm. Regarding each of the insulating substrates 101 of group 2C, the step height of the surface was 0.18 to 0.19 μm.

Regarding each of the insulating substrates 101 of group 2D, the recessed portions positioned at the contact holes CH and the gaps between the pixel electrodes were filled with the cover members CV without formation of the partition. Specifically, the cover members CV were formed by supplying thermosetting resin to the recessed portions and the gaps by inkjet printing and heat-curing it with a heat treatment at 150° C. for 2 hours. Regarding each of the insulating substrates 101 of group 2D, the step height of the surface, that is, the step height of the top surface of the pixel electrode with respect to the top surface of the cover member CV was 0.07 to 0.09 μm.

Subsequently, with use of the deposition apparatus which performs vacuum evaporation by an electrical resistance heating method, a hole-transporting layer, emitting layers, an electron-transporting layer, electron injection layer, and counter electrode CE were sequentially formed on each of the insulating substrates 101 of group 2A. As a material of the counter electrode CE, magnesium and silver were used. These emitting layers were formed with use of a high precision metal mask. Specifically, a red emitting layer emitting red light, green emitting layer emitting green light, and blue emitting layer emitting blue light were formed for the organic EL elements OLED1 to OLED3, respectively. As described above, the array substrate 100 was obtained.

On each of the insulating substrates 101 of groups 2B to 2D, a hole-transporting layer, emitting layers, an electron-transporting layer, electron injection layer, and counter electrode CE were sequentially formed.

Specifically, a hole-transporting layer and a red emitting layer including the first dopant emitting red light were formed without use of a metal mask. Subsequently, each of the insulating substrates 101 was taken out from the deposition apparatus, and the regions of the red emitting layer in which the organic EL elements OLED and OLED 3 should be formed were irradiated with ultraviolet having a main wavelength of 365 nm via a photo mask. Thus, emission of the first dopant included in these regions was inhibited.

Next, each of the insulating substrates 101 was put back into the deposition apparatus, and then a green emitting layer including the second dopant emitting green light was formed on the red emitting layer without use of a metal mask. Subsequently, each of the insulating substrates 101 was taken out from the deposition apparatus, and the regions of the green emitting layer in which the third organic EL elements OLED3 should be formed were irradiated with ultraviolet having a main wavelength of 365 nm via a photo mask. Thus, emission of the second dopant included in this region was inhibited.

After that, each of the insulating substrates 101 was put back into the deposition apparatus, a blue emitting layer including the third dopant emitting blue light was formed on the green emitting layer without use of a metal mask. Subsequently, on the blue emitting layer, an electron-transporting layer, electron injection layer and counter electrode CE were formed sequentially. As a material of the counter electrode CE, magnesium and silver were used. Thus, the array substrates 100 were obtained.

Next, as the sealing substrates 200, twenty glass substrates were prepared. On each of the sealing substrates 200, an ultraviolet curing resin as a sealing material was applied in a frame shape using a dispenser. Further, on each of the sealing substrates 200 and on the inside of frame of the sealing material, an appropriate amount of thermosetting resin for forming the resin layer 300 was dropped.

Subsequently, these sealing substrate 200 and array substrate 100 were bonded together in a vacuum chamber such that the ultraviolet curing resin and thermosetting resin were interposed therebetween. After that, the ultraviolet curing resin was cured by ultraviolet irradiation. Further, the thermosetting resin was heat-cured by heating in an oven at 100° C. for 3 hours. As described above, the display panels 1 were obtained.

Signal supply sources were mounted to each of the display panels 1, and it was subjected to a lighting test. In the lighting test, the number of the panels in which exfoliation of films occurred was counted by observing the screens while each of the display panels was kept on. The results are summarized in Table 2.

TABLE 2

| | | | | | | | Number of |
|---|---|---|---|---|---|---|---|
| | | | | | | | display |
| | | | | | | | panels in |
| | | | | | | Step | which |
| | | | | | | height of | detachment |
| | | 1st | Thickness of | Thickness of | Structure | array | of thin |
| | | interlayer | reflecting | transmitting | of cover | substrate | film |
| Group | Partition | insulator | layer (nm) | layer (nm) | member | (μm) | occurred |
| 2A | Present | Present | 80 | 50 | Absent | 2.0-2.1 | 5 |
| 2B | Absent | Present | 80 | 50 | Islands | 0.19-0.2 | 0 |
| 2C | Absent | Absent | 80 | 50 | Islands | 0.18-0.19 | 0 |
| 2D | Absent | Present | 100 | 100 | Grid- | 0.07-0.09 | 0 |
| | | | | | shaped | | |

Each of the display panels of group 2A included the partition. Regarding group 2A, exfoliation occurred in all of the display panels.

Each of the display panels of groups 2B to 2D did not include a partition. Regarding each of groups 2B to 2D, exfoliation did not occur in all of the display panels.

The results obtained for group 2B and 2C indicates that presence and absence of the first interlayer insulator 114, which is the passivation film, does not have an influence on occurrence of exfoliation. Further, as the case for group 2D, even though the pixel electrodes PE are thicker, occurrence of exfoliation could be prevented by filling the gaps between the pixel electrodes PE with the cover members CV.

As described above, exfoliation of films caused by concentration of stress can be prevented by reducing the step height of the surface of the array substrate 100.

Next, the sixth embodiment will be described below.

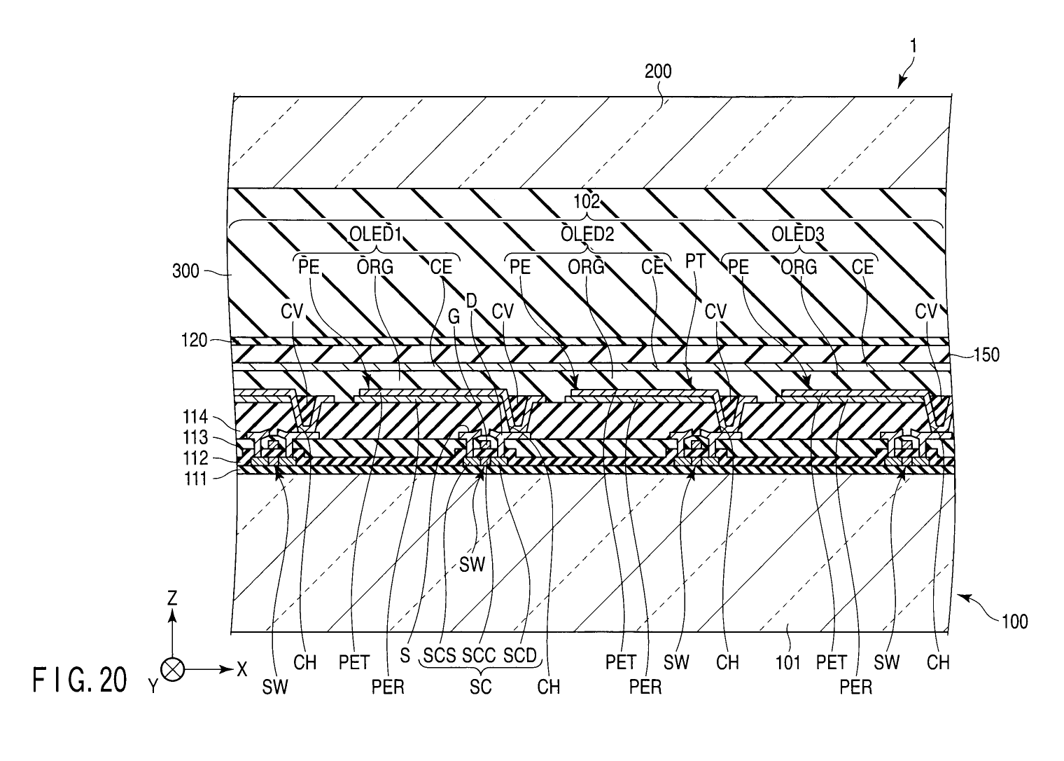

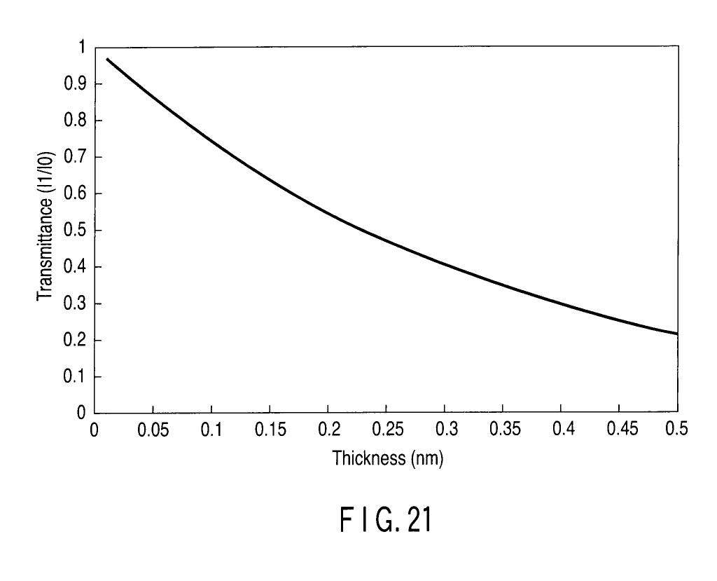

The sixth embodiment relates to an organic EL display that employs the active matrix driving method. The organic EL display of the sixth embodiment is described with reference to FIGS. 20 and 21.

The organic EL display of the sixth embodiment is the same as the organic EL display described with reference to FIGS. 14 to 16 except that the following structure is employed.

That is, in this embodiment the array substrate 100 does not include an interlayer insulator 115 as shown in FIG. 20. The array substrate 100 may further include the interlayer insulator 115. Alternatively, the array substrate 100 may include the interlayer insulator 115 but may not include an interlayer insulator 114.

The array substrate 100 further includes a protective layer 150 between the counter electrode CE and the sealing layer 120. The protective layer 150 is provided over the counter electrode CE. The protective layer 150 is a continuous layer extending over almost the entire active area 102. The protective layer 150 is made of a material including an ultraviolet absorbing agent having a light-transmitting property and absorbing ultraviolet. For example, the protective layer 150 is made of an organic compound such as an organic EL material included in the organic layer ORG. A material of the protective layer 150 desirably exhibits a high transmittance for the light emitted by each of the organic EL elements. The protective layer 150 serves as an ultraviolet-reducing layer which reduces ultraviolet ray reaching to the organic EL elements OLED1 to OLED3 from a counter substrate 200 side.

The filler layer 300 is formed from, for example, ultraviolet curing resin or thermosetting resin. Here, as an example, the filler layer 300 is formed from ultraviolet curing resin.

According to the sixth embodiment, the same effect can be obtained as that obtained by the fourth embodiment.

Further, according to the sixth embodiment, when an outer light enters from the counter substrate 200 side, the protective layer 150 absorbs ultraviolet ray included in this outer light. Therefore, deterioration of the organic EL elements OLED1 to OLED3 by ultraviolet, in particular deterioration of the emitting layers included in the organic layer ORG can be suppressed.

In particular, in the display panel 1 in which the emitting layers are partially quenched by ultraviolet irradiation, there is some possibility that the emitting layers change the property upon absorbance of ultraviolet ray. Therefore, in such a display panel 1, it is desirable to inhibit alteration of the luminous color caused by ultraviolet absorption by the emitting layers. As described above, this display panel 1 includes the protective layer 150, and thus the luminous color is difficult to change even in an environment where it is irradiated with ultraviolet.

In the case where the filler layer 300 is formed from an ultraviolet curing resin, the resin is irradiated with ultraviolet ray for curing. In this case, the organic layer ORG is also irradiated with a portion of the ultraviolet for curing treatment. When the protective layer 150 is interposed between the organic EL elements OLED1 to OLED3 and the filler layer 300, alteration of the luminous color with a curing treatment of resin can be prevented.

In general, light transmittance, that is, the ratio of transmitted light intensity I1 with respect to incident light intensity I0 is expressed by the following equation.

I1/I0=exp(−2ωκ/C·Z)=exp(−4Πκ/λ/n·Z)

Here, ω, λ, κ, n, C, and Z indicate angular frequency, wavelength, absorption coefficient, refractive index, light velocity, and film thickness, respectively.

As clear from the above equation, for example, when κ/n·Z is maximized, the ultraviolet absorption by the protective layer 150 can be maximized, that is, the amount of light transmitted by the protective layer 150 can be minimized. Therefore, adjustment of the film thickness Z of the protective layer 150 enables reduction of damages of the organic layer ORG due to ultraviolet.

In particular, it is preferable that the protective layer 150 is made of an organic EL material, which makes it possible to use a property that the organic EL material easily absorbs ultraviolet. The protective layer 150 made of such materials can be formed by methods such as application and evaporation.

FIG. 21 is a graph showing an example of relation between film thickness of the protective layer 150 (μm) and the ultraviolet transmittance (I1/I0). Here, the refractive index n and absorption coefficient κ are 2.02 and 0.18, respectively, and wavelength λ of the ultraviolet which enters into the protective layer 150 is 365 nm.

As shown, as the protective layer 150 becomes thick, ultraviolet transmittance is reduced. In order to reduce the transmittance to 50% or less, the film thickness of the protective layer 150 is desirably about 0.2 μm or more.

Next, the seventh embodiment will be described below.

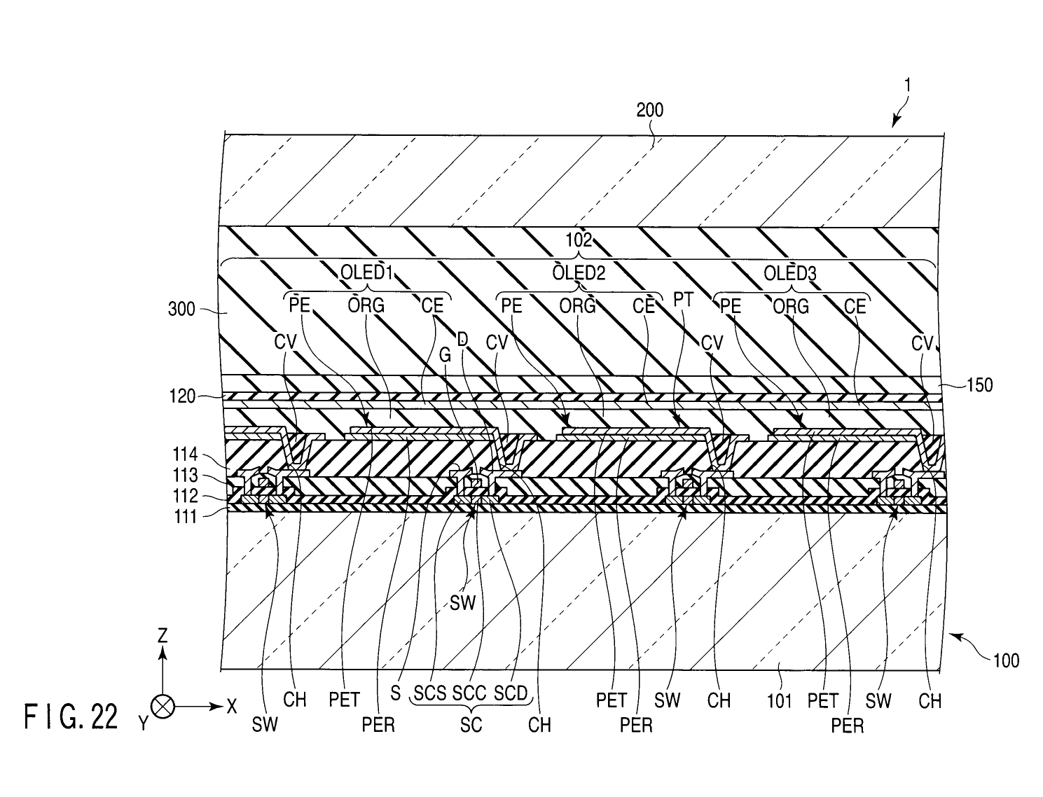

The seventh embodiment relates to an organic EL display that employs the active matrix driving method. The organic EL display is explained with reference to FIG. 22.

The organic EL display of the seventh embodiment is the same as the organic EL display described with reference to FIGS. 20 and 21 except that the following structure is employed.

That is, in this embodiment, the protective layer 150 is interposed between the sealing layer 120 and filler layer 300 as shown in FIG. 22. Also in the case where such a structure is employed, the same effect can be obtained as that obtained by the sixth embodiment.

Regarding the organic EL display of the sixth and seventh embodiments, influence of ultraviolet irradiation on luminous efficiency of the organic EL elements was studied. Here, the covering layer CV was omitted.

As the first mother substrates 3A to 3G, seven glass substrates having a 400 mm×500 mm rectangular shape were prepared. On each of the first mother substrates 3A to 3G, switching elements SW, the first insulating layer 111, second insulating layer 112, third insulating layer 113, fourth insulating layer 114, reflecting layers PER and transmitting layers PET of pixel electrodes PE and the like were formed. On each of the first mother substrates, the switching elements SW and the like were arranged such that twenty four array substrates 100 having the active area 102 of a 3.5-inch diagonal size were obtained. Here, as the switching elements SW, low temperature polysilicon TFTs each provided with a polysilicon film as a semiconductor layer were formed.

Next, on each of the first mother substrates 3A to 3G, a hole-transporting layer, emitting layers, an electron-transporting layer, electron injection layer, and counter electrode CE were formed sequentially using a deposition apparatus which performs vacuum evaporation by the electrical resistance heating method.

Specifically, without use of a metal mask, the hole-transporting layer and the red emitting layer including the first dopant emitting red light were formed. Subsequently, each of the first mother substrates 3A to 3G was taken out from the deposition apparatus, and the regions of the red emitting layer in which the organic EL elements OLED2 and OLED3 should be formed were irradiated with ultraviolet light having a main wavelength of 365 nm via a photo mask. Thus, emission of the first dopant included in these regions was inhibited.

Next, each of the first mother substrates 3A to 3G was put back into the deposition apparatus, and then a green emitting layer including the second dopant emitting green light was formed on the red emitting layer without use of a metal mask. Subsequently, each of the first mother substrates 3A to 3G was taken out from the deposition apparatus, and the regions of the green emitting layer in which the third organic EL elements OLED3 should be formed were irradiated with ultraviolet light having a main wavelength of 365 nm via a photo mask. Thus, emission of the second dopant included in these regions was inhibited.

After that, each of the first mother substrates 3A to 3G was put back into the deposition apparatus, and then a blue emitting layer including the third dopant emitting blue light was formed on the green emitting layer without use of a metal mask. Subsequently, on the blue emitting layer, an electron-transporting layer, electron injection layer, and counter electrode CE were sequentially formed. As a material of the counter electrode CE, magnesium and silver were used.

Subsequently, regarding each of the first mother substrate 3A to 3G, the sealing layer 120 and protective layer 150 were formed on the counter electrode CE, following the procedure described below.

That is, regarding the first mother substrate 3A, a film made of silicon nitride (SiN) and having a film thickness of 1 μm was formed as the sealing layer 120 on the counter electrode CE. Regarding the first mother substrate 3A, the protective layer 150 was not formed. Therefore, the value of κ/n·Z is zero.

Regarding the first mother substrates 3B to 3D, the protective layer 150 made of an organic EL material was formed on the counter electrode CE using the deposition apparatus which performs vacuum evaporation by the electrical resistance heating method. Sequentially, a film made of silicon nitride (SiN) and having a thickness of 1 μm was formed as the sealing layer 120 on the protective layer 150 by the plasma CVD method.

Specifically, regarding the first mother substrate 3B, the film thickness of the protective layer 150 was 100 nm. Therefore, the value of κ/n·Z for the first mother substrate 3B was 8.91 nm.

Regarding the first mother substrate 3C, the film thickness of the protective layer 150 was 200 nm. Therefore, the value of κ/n·Z for the first mother substrate 3C was 17.82 nm.

Regarding the first mother substrate 3D, the film thickness of the protective layer 150 was 300 nm. Therefore, the value of κ/n·Z for the first mother substrate 3D was 26.73 nm.

Regarding the first mother substrates 3E to 3G, a film made of silicon nitride (SiN) and having a thickness of 1 μm was formed as the sealing layer 120 on the counter electrode CE by the plasma CVD method. Subsequently, the protective layer 150 made of an organic EL material was formed using the deposition apparatus which performs vacuum evaporation by the electrical resistance heating method.

Specifically, regarding the first mother substrate 3E, the film thickness of the protective layer 150 was 100 nm. Therefore, the value of κ/n·Z for the first mother substrate 3E was 8.91 nm.

Regarding the first mother substrate 3F, the film thickness of the protective layer 150 was 200 nm. Therefore, the value κ/n·Z for the first mother substrate 3F was 17.82 nm.

Regarding the first mother substrate 3G, the film thickness of the protective layer 150 was 300 nm. Therefore, the value κ/n·Z for the first mother substrate 3G was 26.73 nm.

Here, regarding the organic EL materials used as materials of the protective layer 150 of the first mother substrates 3B to 3G, absorption coefficient K for ultraviolet light having a wavelength of 365 nm and refractive index n were 0.18 and 2.02, respectively.

Next, as the second mother substrates, seven glass substrates were prepared. Each of the second mother substrates had sufficient size for obtaining twenty four sealing substrates 200.

On each of the second mother substrates, ultraviolet curing resin for forming a sealing member was applied with use of a dispenser such that twenty four frames were formed. Then, on the inside of each of the frames, an appropriate amount of ultraviolet curing resin for forming the filler layer 300 was dropped. Subsequently, these second mother substrates and the first mother substrates 3A to 3G were bonded together in a vacuum chamber such that ultraviolet curing resin was interposed therebetween.

After that, the ultraviolet resin was cured by irradiating the ultraviolet curing resin with ultraviolet ray from a second mother substrate's side. Here, the irradiated ultraviolet had a main wavelength of 365 nm. At a wavelength of 365 nm, the energy was 5 J/cm².

Then, each of the combinations of first and second mother substrates was broken into twenty four display panels 1. Signal supply sources were further mounted to each of the display panels 1.

The group including twenty four display panels and obtained using the first mother substrate 3A is referred to as group A. Similarly, groups each including twenty four display panels and obtained using the first mother substrates 3B to 3G are referred to as groups 3B to 3G, respectively.

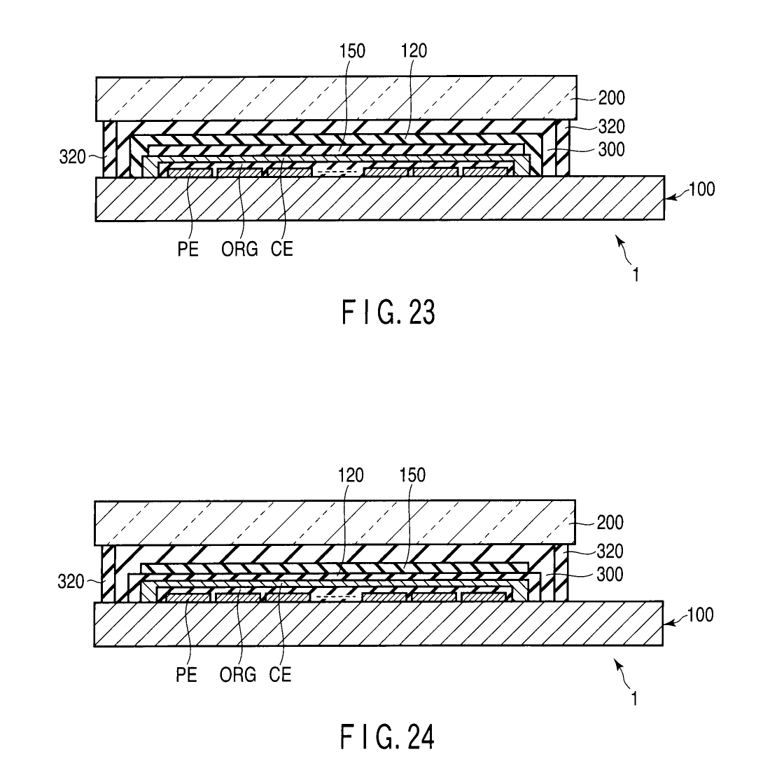

FIG. 23 is a sectional view schematically showing the display panels 1 of groups 3B to 3D. FIG. 24 is a sectional view schematically showing the display panels 1 of groups 3E to 3G. In FIGS. 23 and 24, reference character 320 indicates the sealing member. In FIGS. 23 and 24, a part of components are omitted.

All of the display panels 1 of groups 3A to 3G were turned on, and the luminous efficiency (cd/A) of each of them was determined at a current value of 0.5 mA. Then, the average values of luminous efficiency were calculated for each of the groups 3A to 3G. The results are summarized in Table 3 below.

TABLE 3

| | | κ/n · Z for | Mean luminous |
|---|---|---|---|
| Group | Structure formed on counter electrode | protective layer (nm) | efficiency (cd/A) |
| 3A | Sealing layer (1,000) | 0.00 | 2.1 |
| 3B | Protective layer (100)/Sealing layer (1,000) | 8.91 | 3.2 |
| 3C | Protective layer (200)/Sealing layer (1,000) | 17.82 | 4.5 |
| 3D | Protective layer (300)/Sealing layer (1,000) | 26.73 | 4.8 |
| 3E | Sealing layer (1,000)/Protective layer (100) | 8.91 | 3.1 |
| 3F | Sealing layer (1,000)/Protective layer (200) | 17.82 | 4.6 |
| 3G | Sealing layer (1,000)/Protective layer (300) | 26.73 | 4.9 |

Notes:
Numerical value within parentheses is thickness in nanometer.
Element following slash mark was formed after forming element preceding slash mark.

Each display panel of group 3A did not include the protective layer 150. Thus, due to the influence of the ultraviolet irradiation in the step of forming the seal member 30 and filler layer 320, the organic layers ORG of the organic EL elements OLED1 to OLED3 were damaged. Therefore, the average of the luminous efficiency was remarkably low and the average thereof was 2.1 cd/A.

Each display panel of groups 3B to 3G included the protective layer 150. Therefore, the influence of ultraviolet ray was reduced, and higher luminous efficiency could be achieved as compared with group 3A. Specifically, the luminous efficiencies of groups 3B, 3C, 3D, 3E, 3F, and 3G were 3.2 cd/A, 4.5 cd/A, 4.8 cd/A, 3.1 cd/A, 4.6 cd/A, and 4.9 cd/A, respectively.

The results obtained for groups 3B to 3D or the results obtained from groups 3E to 3G show that as the protective layer 150 becomes thicker, deterioration of the organic EL elements OLED1 to OLED3 caused by the ultraviolet irradiation can be prevented and higher luminous efficiency can be obtained.

Further, the results obtained for groups 3B and 3E, the results obtained for groups 3C and 3F or the results obtained for groups 3D and 3G show that the effect in preventing the deterioration of the organic EL elements OLED1 to OLED3 caused by ultraviolet irradiation was not dependent on the stacking order of the sealing layer 120 and protective layer 150.

As described above, a display panel achieving high luminous efficiency can be obtained by inserting the protective layer 150 capable of absorbing ultraviolet ray between the counter electrode CE and the sealing layer 120 or the sealing layer 120 and the filler layer 320.

Various modifications can be made to the techniques described in the first to seventh embodiments. Some modified examples will be described below.

The display panels 1 described in the first to seventh embodiments are top emission types. The techniques described above can be applied to display panels of bottom emission types in which the pixel electrodes PE do not include a reflecting layer.

A part of the components may be omitted from the display panels 1 described in the first to seventh embodiments.

Two or more of the techniques described in the first to seventh embodiments can be combined. For example, the display panels 1 described in the first to fifth embodiments may further include one or more of the sealing layer 120, protective layer 150, and filler layer 300.

The aforementioned techniques can be applied to organic EL devices other than the organic EL display. For example, the aforementioned techniques can be applied to an organic EL lighting apparatus or organic EL printer head.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An organic EL device comprising:
an insulating substrate;
switching elements arranged two-dimensionally above the insulating substrate;
an insulating layer positioned above the switching elements and provided with contact holes communicating with the switching elements, respectively;
pixel electrodes arranged correspondingly with the switching elements and each including an electrode body positioned above the insulating layer and a contact section extending in the contact hole and electrically connecting the electrode body to the switching element;
cover members arranged correspondingly with the contact holes, each of the cover members covering the contact section and made of an insulating material;
an organic layer extending over the pixel electrodes, the cover members and a portion of the insulating layer positioned below a region between the pixel electrodes; and
a counter electrode positioned above the organic layer.

2. The device according to claim 1, wherein the contact section includes a recessed portion extending in a length direction of the contact hole, and each of the cover members includes a first portion filling the recessed portion.

3. The device according to claim 2, wherein each of the cover members further includes a second portion protruding upwardly from the recessed portion, a top surface of the second portion being a convex curved surface.

4. The device according to claim 3, wherein the insulating material is an organic material, the insulating layer includes an organic insulating layer, and each of the cover members is spaced apart from the organic insulating layer.

5. The device according to claim 2, wherein the insulating material is an organic material, the insulating layer includes an organic insulating layer, and each of the cover members is spaced apart form the organic insulating layer.

6. The device according to claim 1, wherein the insulating layer includes an inorganic insulating layer provided with the contact hole and an organic layer positioned above the organic insulating layer, the organic insulating layer is divided into insulating portions by grooves arranged in a grid shape such that the contact holes and portions of the inorganic insulating layer adjacent to the contact holes respectively are exposed at bottoms of the grooves, the contact section covers at least a part of a side surface of the insulating section and at least a part of a sidewall of the contact hole, the insulating material is an organic material, and each of the cover members is spaced apart from the organic insulating layer.

7. The device according to claim 6, wherein each of the pixel electrodes covers whole side surfaces of the insulating portion.

8. The device according to claim 1, wherein differences in height between top surfaces of the pixel electrodes and top surfaces of the cover members are 0.2 μm or less.

9. The device according to claim 1, further comprising:
a protective layer positioned above the organic layer and including an ultraviolet absorber;
a sealing layer positioned above the protective layer;
a counter substrate positioned above the sealing layer; and
a filler layer filling a space between the sealing layer and the counter substrate.

10. An organic EL device comprising:
an insulating substrate;
first to third switching elements arranged above the insulating substrate;
an insulating layer positioned above the first to third switching elements and provided with first to third contact holes communicating with the first to third switching elements, respectively;
a first pixel electrode including a first electrode body positioned above the insulating layer and a first contact section extending in the first contact hole and electrically connecting the first electrode body to the first switching element;
a second pixel electrode including a second electrode body positioned above the insulating layer and a second contact section extending in the second contact hole and electrically connecting the second electrode body to the second switching element;
a third pixel electrode including a third electrode body positioned above the insulating layer and a third contact section extending in the third contact hole and electrically connecting the third electrode body to the third switching element;
first to third cover members each made of an insulating material and covering the first to third contact sections, respectively;
a first organic layer extending over the first to third pixel electrodes, the first to third cover members, and a portion of the insulating layer below a region between any two of the first to third pixel electrodes, the first organic layer emitting light at a portion corresponding to the first pixel electrode and causing quenching at portions corresponding to the second and third pixel electrodes;
a second organic layer extending above the first organic layer, the second organic layer emitting light at portions corresponding to the first and second pixel electrodes and causing quenching at a portion corresponding to the third pixel electrode;
a third organic layer extending above the second organic layer and emitting light at portions corresponding to the first to third pixel electrodes; and
a counter electrode positioned above the third organic layer.

11. The device according to claim 10, wherein the first organic layer emits red light at the portion corresponding to the first pixel electrode, the second organic layer emits green light at the portion corresponding to the second pixel electrode, and the third organic layer emits blue light at a portion corresponding to the third pixel electrode.

12. The device according to claim 10, wherein the first to third contact sections include recessed portions extending in length directions of the first to third contact holes, respectively, and each of the first to third cover members includes a first portion filling the recessed portion.

13. The device according to claim 12, wherein each of the first to third cover members further includes a second portion protruding upwardly from the recessed portion.

14. The device according to claim 13, wherein the insulating material is an organic material, the insulating layer includes an organic insulating layer, and each of the first to third cover members is spaced apart from the organic insulating layer.

15. The device according to claim 12, wherein the insulating material is an organic material, the insulating layer includes an organic insulating layer, and each of the first to third cover members is spaced apart from the organic insulating layer.

16. The device according to claim 10, wherein the insulating layer includes an inorganic insulating layer provided with the first to third contact holes and an organic layer positioned above the organic insulating layer, the organic insulating layer is divided into insulating portions by grooves arranged in a grid shape such that the first to third contact holes and portions of the inorganic insulating layer adjacent to the first to third contact holes respectively are exposed at bottoms of the grooves, each of the first to third contact sections covers at least a part of a side surface of the insulating section and at least a part of a sidewall of one of the first to third contact holes, the insulating material is an organic material, and each of the first to third cover members is spaced apart from the organic insulating layer.

17. The device according to claim 16, wherein each of the first to third pixel electrodes covers whole side surfaces of the insulating portion.

18. The device according to claim 10, wherein differences in height between top surface of the first to third pixel electrodes and top surface of the first to third cover members are 0.2 μm or less.

19. The device according to claim 1, further comprising:
a protective layer positioned above the third organic layer and including an ultraviolet absorber;
a sealing layer positioned above the protective layer;
a counter substrate positioned above the sealing layer; and
a filler layer filling a space between the sealing layer and the counter substrate.

20. An organic EL device comprising:
an insulating substrate;
switching elements two-dimensionally arranged above the insulating substrate;
pixel electrodes arranged correspondingly with the switching elements and each including an electrode body positioned above the insulating layer and a contact section extending in the contact hole and electrically connecting the electrode body to the switching element;
a cover member made of an insulating material and covering the contact section and a portion of the insulating layer positioned below a region between the pixel electrodes;
an organic layer extending over the pixel electrodes and the cover member; and
a counter electrode positioned above the organic layer.
